(19) United States
(12) Patent Application Publication
(10) Pub. No.: US 2025/0301692 A1
(43) Pub. Date: Sep. 25, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Yi-Hong WANG, Taichung City (TW); Yi-Chen LI, Taichung City (TW)

(21) Appl. No.: 18/614,291

(22) Filed: Mar. 22, 2024

(51) Int. Cl. H01L 29/78; H01L 21/8238; H01L 27/092; H01L 29/06; H01L 29/08; H01L 29/423; H01L 29/66; H01L 29/775; H01L 29/786

(52) U.S. Cl. CPC H10D 30/6211; H10D 30/014; H10D 30/024; H10D 30/43; H10D 30/6735; H10D 30/6757; H10D 62/121; H10D 62/151; H10D 64/017; H10D 84/017; H10D 84/0193; H10D 84/038; H10D 84/853

(57) ABSTRACT

Some implementation described herein include a semiconductor device including a transistor structure and methods of manufacturing. The transistor structure, a tunneling fin field effect transistor structure, includes different combinations of doped semiconductor regions that form a source region, a drain region, and a channel region of the transistor structure. The different combinations of doped semiconductor regions include different types of dopants, different concentrations of dopants, and/or dopant gradients that change differences in band gap energy levels across one or more junctions of the transistor structure to increase a threshold voltage and/or decrease a leakage in the transistor structure.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). A source region and a drain region (e.g., epitaxial regions) are located on opposing sides of the gate structure and/or the channel region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams related to a semiconductor device including a transistor structure described herein.

FIGS. 3A, 3B, 4A, 4B, 5A-5C, 6A, 6B, 7A, 7B, 8A-8C, and 9 are diagrams of one or more implementations described herein.

FIGS. 10A-10I, 11A-11C, and 12A-12C are diagrams of example series of semiconductor manufacturing operations used to form one or more portions of a semiconductor device including a transistor structure described herein.

FIG. 13 is a diagram of example performance data of a transistor structure described herein.

FIG. 14 is a diagram of example components of one or more devices of FIG. 1 described herein.

FIG. 15 is a flowchart of an of example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Types of finFET structures include a metal oxide field effect transistor (MOSFET) and a tunneling field effect transistor (TFET), among other examples. By relying on quantum mechanical tunneling of charge carriers through a junction between a source region and a channel region, the TFET structure may have a lower power consumption than the MOSFET structure. Furthermore, a subthreshold slope (SS) of the TFET may be increased relative to the MOSFET to provide a better control of current flow and a reduced leakage.

In some cases, a width of the channel region channel of the TFET structure is consistent between a source region and a drain region of the TFET structure. Additionally, or alternatively, dopant profiles of the source region and/or the drain region may be symmetric (e.g., same types of dopants) and/or uniform (e.g., consistent in doping concentrations). In such cases, differences in band gap energy levels across one or more junctions of the TFET structure may form energy barriers that the charge carriers are unable to overcome to flow through the channel region without increasing a voltage that is applied to a gate of the TFET structure (e.g., a threshold voltage). Increasing the voltage may, in turn, not satisfy a threshold corresponding to an available supply voltage in a semiconductor device that includes the TFET structure.

Some implementation described herein include a semiconductor device including a TFET structure and methods of manufacturing. The TFET structure includes different combinations of doped semiconductor regions that form a source region, a drain region, and a channel region of the TFET. The different combinations of doped semiconductor regions include different types of dopants, different concentrations of dopants, and/or dopant gradients that change differences in band gap energy levels across one or more junctions of the TFET structure.

In this way, a performance of the TFET structure is increased such that the TFET structure is compatible with an available power supply. Furthermore, leakage within the TFET structure may be reduced to increase a quality and/or a reliability of the TFET structure.

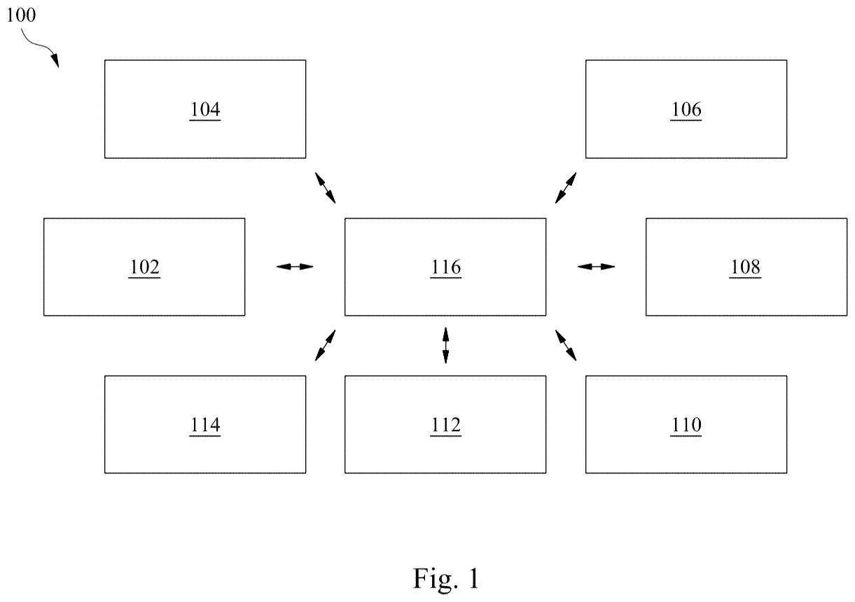

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer over and/or on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, a plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or the like.

The ion implantation tool 114 is a semiconductor processing tool that is used to implant ions into a substrate such as a semiconductor wafer. The ion implantation tool 114 generates ions in an arc chamber from a source material such as a gas or a solid. The source material is provided into the arc chamber, and an arc voltage is discharged between a cathode and an electrode to produce a plasma containing ions of the source material. One or more extraction electrodes are used to extract the ions from the plasma in the arc chamber and accelerate the ions to form an ion beam. The ion beam may be directed toward the substrate such that the ions are implanted below the surface of the substrate to dope the substrate.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

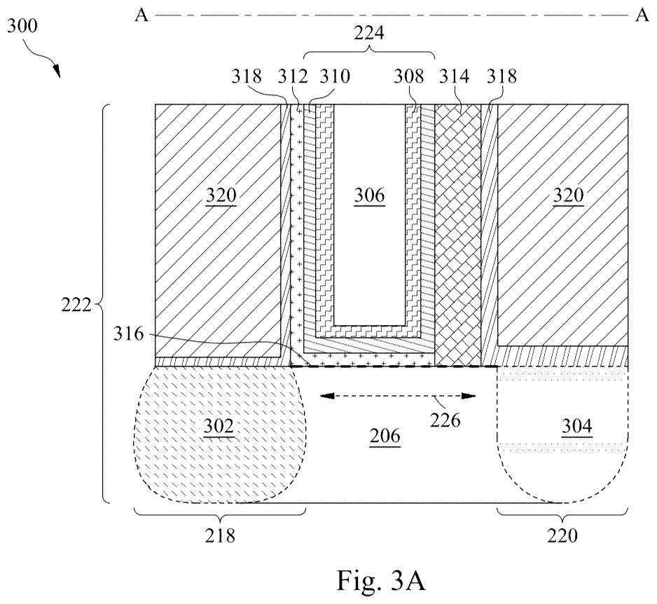

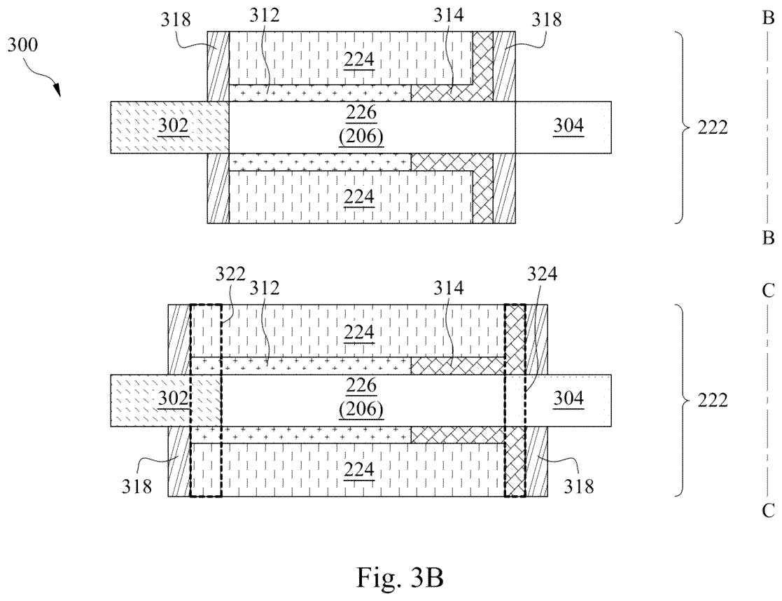

In some implementations, and as described in greater detail in connection with FIGS. 3A-15 and elsewhere herein, the plurality of semiconductor processing tools 102-114 and/or the wafer/die transport tool 116 performs a series of semiconductor manufacturing operations. The series of semiconductor manufacturing operations includes forming a dummy gate structure on and above a fin structure, where the dummy gate structure includes a gate electrode layer that is surrounded by a multi-layer sidewall including a first dielectric layer that is on the gate electrode layer. The series of semiconductor manufacturing operations includes forming a source region including a first doped semiconductor region having a p-type dopant in the fin structure below the dummy gate structure and adjacent to a first side of the dummy gate structure. The series of semiconductor manufacturing operations includes forming a drain region including a second doped semiconductor region having a first n-type dopant below the dummy gate structure and adjacent to a second, opposite side of the dummy gate structure. The series of semiconductor manufacturing operations includes removing the gate electrode layer. The series of semiconductor manufacturing operations includes removing a portion of the first dielectric layer to expose a portion of the fin structure adjacent to the source region and a second dielectric layer of the multi-layer sidewall. The series of semiconductor manufacturing operations includes forming a pocket region including third doped semiconductor region having a second n-type dopant in the portion of the fin structure adjacent to the source region. The series of semiconductor manufacturing operations includes forming a third dielectric layer over the pocket region and along the second dielectric layer. The series of semiconductor manufacturing operations includes forming a gate structure between the third dielectric layer and a remaining portion of the first dielectric layer, where forming the gate structure includes forming one or more layers of a conductive material between the third dielectric layer and the remaining portion of the first dielectric layer.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

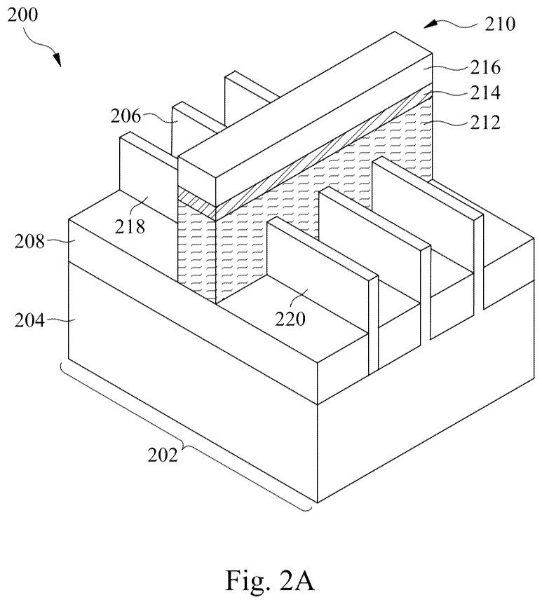

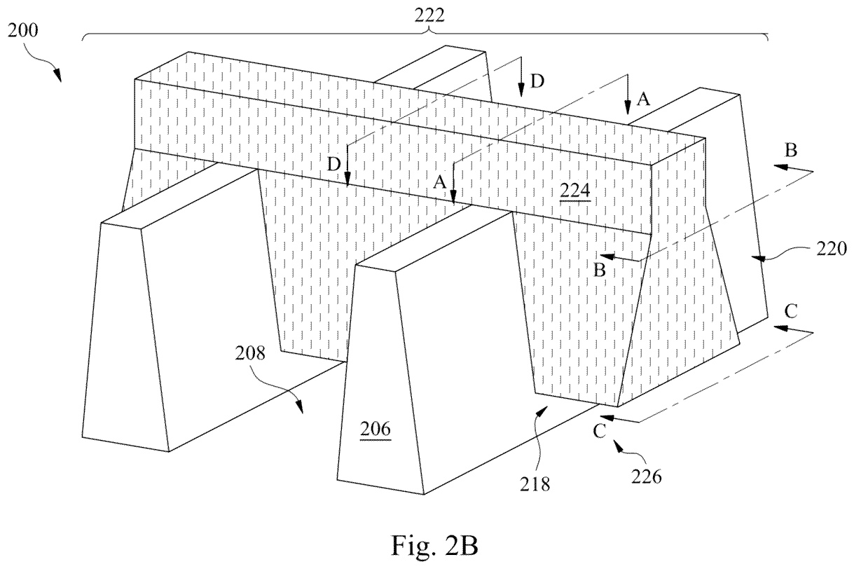

FIGS. 2A and 2B are diagrams related to a semiconductor device including a transistor structure described herein. In particular, FIGS. 2A and 2B illustrate an example device region 202 of the semiconductor device 200 in which one or more transistors or other devices are included. The transistors may include fin-based transistors, such as fin field effect transistors (finFETs), nanostructure transistors, and/or other types of transistors. In some implementations, the device region 202 includes a p-type metal oxide semiconductor (PMOS) region, an n-type metal oxide semiconductor (NMOS) region, a complementary metal oxide semiconductor (CMOS) region, and/or another type of device region. FIGS. 3A-12C include schematic cross-sectional views of various portions of the device region 202 of the semiconductor device 200 illustrated in FIGS. 2A and 2B and correspond to various processing stages of forming fin-based transistors in the device region 202 of the semiconductor device 200.

As shown in the isometric view of FIG. 2A, the semiconductor device 200 includes a substrate 204. The substrate 204 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, or another type of semiconductor substrate. The substrate 204 may include a round/circular substrate having an approximately 200 mm diameter, an approximately 300 mm diameter, or another diameter, such as 450 mm, among other examples. The substrate 204 may alternatively be any polygonal, square, rectangular, curved, or otherwise non-circular workpiece, such as a polygonal substrate.

Fin structures 206 are included above (and/or extend above) the substrate 204 for the device region 202. A fin structure 206 may provide an active region where one or more devices (e.g., fin-based transistors) are formed. In some implementations, the fin structures 206 include silicon (Si) materials or another elementary semiconductor material such as germanium (Ge). In some implementations, the fin structures 206 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof. In some implementations, a channel region is part of and/or proximate to the fin structures 206.

The fin structures 206 are fabricated by suitable semiconductor process techniques, such as masking, photolithography, and/or etch processes, among other examples. As an example, the fin structures 206 may be formed by etching a portion of the substrate 204 away to form recesses in the substrate 204. The recesses may then be filled with isolating material that is recessed or etched back to form shallow trench isolation (STI) regions 208 above the substrate 204 and between the fin structures 206. Other fabrication techniques for the STI regions 208 and/or for the fin structures 206 may be used. The STI regions 208 may electrically isolate adjacent active areas in the fin structures 206. The STI regions 208 may include a dielectric material such as a silicon oxide (SiOx), a silicon nitride (SixNy), a silicon oxynitride (SiON), fluoride-doped silicate glass (FSG), a low-k dielectric material, and/or other suitable insulating material. The STI regions 208 may include a multi-layer structure, for example, having one or more liner layers.

A dummy gate structure 210 (or a plurality of dummy gate structures 210) is included in the device region 202 over the fin structures 206 (e.g., approximately perpendicular to the fin structures 206). The dummy gate structure 210 engages the fin structures 206 on three or more sides of the fin structures 206. In the example depicted in FIG. 2A, the dummy gate structure 210 includes a gate electrode layer 212, a hard mask layer 214, and/or a capping layer 216, among other examples. In some implementations, the dummy gate structure 210 further includes a gate dielectric layer, one or more spacer layers, and/or another suitable layer. The various layers of the dummy gate structure 210 may be formed by suitable deposition techniques and patterned by suitable photolithography and etching techniques.

The term, “dummy”, as described here, refers to a sacrificial structure which will be removed in a later stage and will be replaced with another structure, such as a high dielectric constant (high-k) dielectric and metal gate structure in a replacement gate process. The replacement gate process refers to manufacturing a gate structure at a later stage of the overall gate manufacturing process. Accordingly, the configuration of the semiconductor device 200 illustrated in FIG. 2A may include an intermediate configuration, and additional semiconductor processing operations may be performed for the semiconductor device 200 to further process the semiconductor device 200.

The gate electrode layer 212 may include a polysilicon (PO) material or another suitable material. The gate electrode layer 212 may be formed by suitable deposition processes such as LPCVD or PECVD, among other examples. The hard mask layer 214 may include any material suitable to pattern the gate electrode layer 212 with particular features/dimensions on the substrate 204, such as a silicon nitride (SixNy) among other examples. The capping layer 216 may include a dielectric oxide layer. The dielectric oxide layer may be formed by chemical oxidation, thermal oxidation, ALD, CVD, and/or other suitable methods.

In some implementations, the various layers of the dummy gate structure 210 are first deposited as blanket layers. Then, the blanket layers are patterned through a process including photolithography and etching processes, removing portions of the blanket layers and keeping the remaining portions over the STI regions 208 and the fin structures 206 to form the dummy gate structure 210.

Source regions 218 and drain regions 220 are disposed in opposing regions of the fin structures 206 with respect to the dummy gate structure 210. The source regions 218 and/or the drain regions 220 are semiconductor regions in which impurities (e.g., dopants) are introduced to a semiconductor material (e.g., silicon or a type III-V material) to alter a conductivity, a charge carrier concentration, and/or an electronic behavior of the semiconductor region.

In some implementations, dopants include a p-type dopant that causes an abundance of positively charged holes within a crystal lattice of a semiconductor region (e.g., in other words, the region is a hole-rich semiconductor region). Examples of p-type dopants include a type-III chemical elements such as boron (B), gallium (Ga), and/or (Al). Furthermore, concentrations of the p-type dopants may be selected based on a desired conductivity, charge carrier concentration, and/or electronic behavior of the semiconductor region. As an example, a selected concentration of a p-type dopant for a heavily-doped semiconductor region (e.g., a P+ semiconductor region) may be in a range of approximately 1×10¹⁸ atoms per cubic centimeter (atoms/cm³) to approximately 1×10²⁰ atoms/cm³. Additionally, or alternatively, a selected concentration of a p-type dopant for a moderately-doped semiconductor region (e.g., a P semiconductor region) may be in a range of approximately 1×10¹⁶ atoms per cubic centimeter (atoms/cm³) to approximately 1×10¹⁸ atoms/cm³. Additionally, or alternatively, a selected concentration of a p-type dopant for a lightly-doped semiconductor region (e.g., a P− semiconductor region) may be in a range of approximately 1×10¹⁴ atoms per cubic centimeter (atoms/cm³) to approximately 1×10¹⁶ 0107-0354 atoms/cm³. However, other chemical elements and/or ranges of concentrations related to p-type dopants are within the scope of the present disclosure.

In some implementations, dopants include an n-type dopant that causes an abundance of electrons within the crystal lattice of the semiconductor region (e.g., in other words, the region is an electron-rich semiconductor region). Examples of n-type dopants include type-V chemical elements such as phosphorous (P), arsenic (As), and/or antimony (Sb). Furthermore, concentrations of the n-type dopants may be selected based on a desired conductivity, a charge carrier concentration, and/or an electronic behavior of the semiconductor region. As an example, a selected concentration of an n-type dopant for a heavily-doped semiconductor region (e.g., an N+ semiconductor region) may be in a range of approximately 1×10¹⁸ atoms per cubic centimeter (atoms/cm³) to approximately 1×10²⁰ atoms/cm³. Additionally, or alternatively, a selected concentration of an n-type dopant for a moderately-doped semiconductor region (e.g., an N semiconductor region) may be in a range of approximately 1×10¹⁶ atoms per cubic centimeter (atoms/cm³) to approximately 1×10¹⁸ atoms/cm³. Additionally, or alternatively, a concentration of an n-type dopant selected for a lightly-doped semiconductor region (e.g., an N-semiconductor region) may be in a range of approximately 1×10¹⁴ atoms per cubic centimeter (atoms/cm³) to approximately 1×10¹⁶ atoms/cm³. However, other chemical elements and/or ranges of concentrations related to n-type dopants are within the scope of the present disclosure.

FIG. 2B shows an isometric view of an example TFET structure 222 in the device region 202 after the replacement gate process. As shown in FIG. 2B, the TFET structure 222 includes a gate structure 224. Portions of the gate structure 224, including one or more layers of conductive material, may be formed on and/or within the fin structures 206 after the replacement gate process. Additionally, and below the gate structure 224, channel regions 226 may be included as part of the fin structures 206. The channel regions 226 may be paths for electrical current and/or charges to flow between the source regions 218 and the drain regions 220 to enable operability of the TFET structure 222.

As described in greater detail in connection with FIGS. 3A-12C, and elsewhere herein, semiconductor regions that are proximate to, or included as part of the fin structures 206, the source regions 218, and/or the drain regions 220 may include different types of dopants (e.g., asymmetric dopants), and/or concentrations of dopants to improve a performance of the TFET structure 222. The improved performance may include reducing a threshold voltage and/or a leakage within the TFET structure 222, among other examples.

FIG. 2B further show references A-A, B-B, C-C, and D-D that are used as references for section views in FIGS. 3A-12C. The reference A-A corresponds to a section view through the fin structure 206. The reference B-B corresponds to a section view through the gate structure 224 proximate an upper portion of the fin structure 206. The reference C-C corresponds to a section view through the gate structure 224 proximate a lower portion of the fin structure 206. The reference D-D corresponds to a section view through the STI region 208 between the fin structures 206.

As indicated above, FIGS. 2A and 2B are provided as an example. Other examples may differ from what is described with regard to FIGS. 2A and 2B.

FIGS. 3A and 3B are diagrams of an example implementation 300 described herein. Implementation 300 shows an example of the semiconductor device 200 in which the source region 218 includes a doped semiconductor region 302 and drain region 220 includes a doped semiconductor region 304. The doped semiconductor regions 302 and 304 include different dopant types (e.g., are asymmetrically doped).

As shown in FIG. 3A, the semiconductor device 200 includes the gate structure 224, the fin structure 206 below the gate structure, the source region 218 along a first side of the fin structure 206, and the drain region 220 along a second side of the fin structure 206. Furthermore, and as shown in FIG. 3A, the channel region 226 is an undoped region of the fin structure 206 between the doped semiconductor region 302 and the drain region 220. In other words, the channel region 226 is an intrinsic fin-shaped semiconductor region.

The source region 218 includes a doped semiconductor region 302 (a doped region of silicon or another type III-V material, among other examples) that is implanted with a p-type dopant. Furthermore, the doped semiconductor region 302 may be a heavily-doped semiconductor region (e.g., a P semiconductor region that includes a heavy concentration of a p-type dopant as described above).

The drain region 220 includes a doped semiconductor region 304 (a doped region of silicon or another type III-V material, among other examples) implanted with an n-type dopant. Furthermore, the doped semiconductor region 304 may be a heavily-doped drain region (e.g., an N semiconductor region that includes a heavy concentration of an n-type dopant as described above).

The gate structure 224 may include a conductive core 306 (a layer of a low-resistance conductive material such as tungsten (W), silver (Ag), or cobalt (Co), among other examples). In some implementations, the gate structure 224 includes a conductive layer 308 that surrounds the conductive core 306. The conductive layer 308 (e.g., a first conductive layer) may include a conductive material such as aluminum (Al), titanium (Ti), tantalum (Ta) or a conductive compound such as titanium aluminum (TiAl) or titanium nitride (TiN), among other examples. Furthermore, and in some implementations, the gate structure 224 includes a conductive layer 310 that surrounds the conductive layer 308. The conductive layer 310 (e.g., a second conductive layer) may include a conductive material such as aluminum (Al), titanium (Ti), tantalum (Ta) or a conductive compound such as titanium aluminum (TiAl) or titanium nitride (TiN), among other examples. The gate structure 224 may include different configurations of the conductive core 306, the conductive layer 308, and/or the conductive layer 310 (e.g., different arrangements of layers, different quantities of layers, different thicknesses of layers, and/or different combinations of materials) to “tune” a performance of the gate structure 224.

As further shown in FIG. 3A, the gate structure includes a dielectric layer 312 and a dielectric layer 314. The dielectric layer 312 (e.g., a first dielectric sidewall) may include a high-k dielectric material (e.g., a material having a higher dielectric constant than silicon dioxide) such as hafnium oxide (HfO₂), zirconium dioxide (ZrO₂), or lanthanum aluminum oxide (LaAlO₃), among other examples. The dielectric layer 314 (e.g., a second dielectric sidewall) may include a low-k dielectric material (e.g., a material having a lower dielectric constant than silicon dioxide) such as a silicon oxynitride (SiON) or a silicon carbon oxynitride (SiCON) among other examples. As further shown in FIG. 3A, the fin structure 206 (e.g., a fin-shaped intrinsic semiconductor region) includes an interface region 316 that connects with the dielectric layers 312 and 314 below the conductive core 306.

In some implementations, and as shown in section view A-A of FIG. 3A, a sidewall spacer layer 318 is on the dielectric layers 312 and 314. The sidewall spacer layer 318 may include silicon nitride (SiN) or silicon carbonitride (SiCN), among other examples. Additionally, and as shown in FIG. 3A, a dielectric layer 320 (e.g., an interlayer dielectric layer (ILD)) is on the sidewall spacer layer 318. The dielectric layer 320 may include a low-k dielectric material such as porous silicon dioxide (SiO₂), among other examples.

FIG. 3B shows section views B-B and C-C of the TFET structure 222. In particular, and as shown in the section view C-C, the TFET structure 222 includes an overlap region 322, in which the doped semiconductor region 302 overlaps the gate structure 224 (e.g., portions of the doped semiconductor region 302 and the gate structure 224 project within a common area). As further shown in the section view C-C, a portion of the dielectric layer 312 is within the overlap region 322.

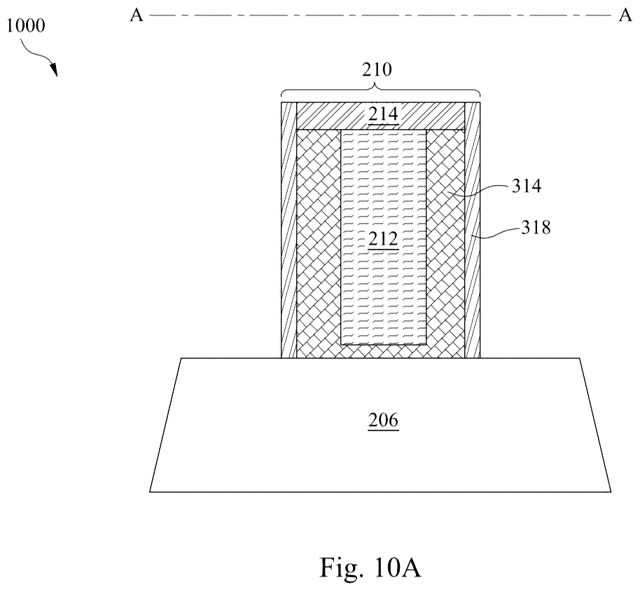

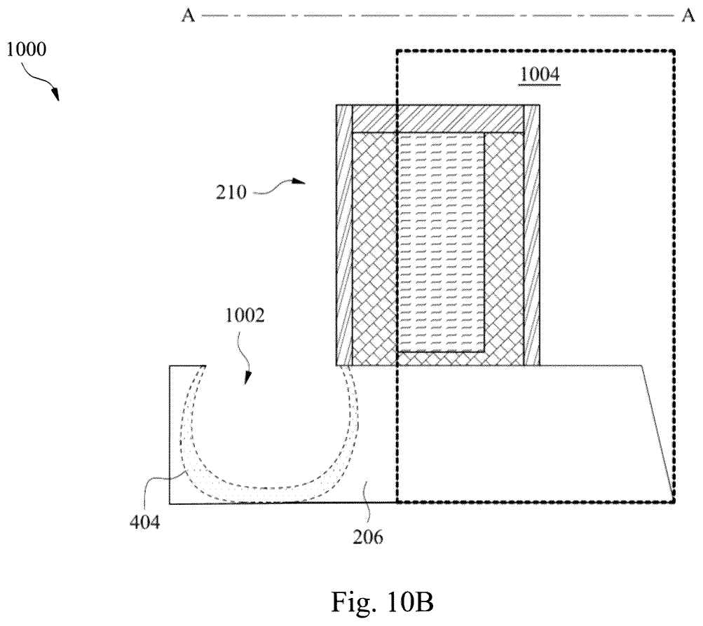

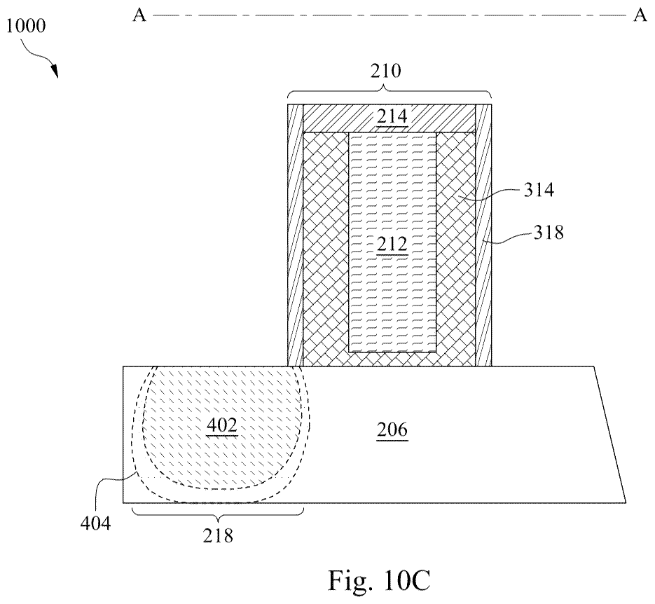

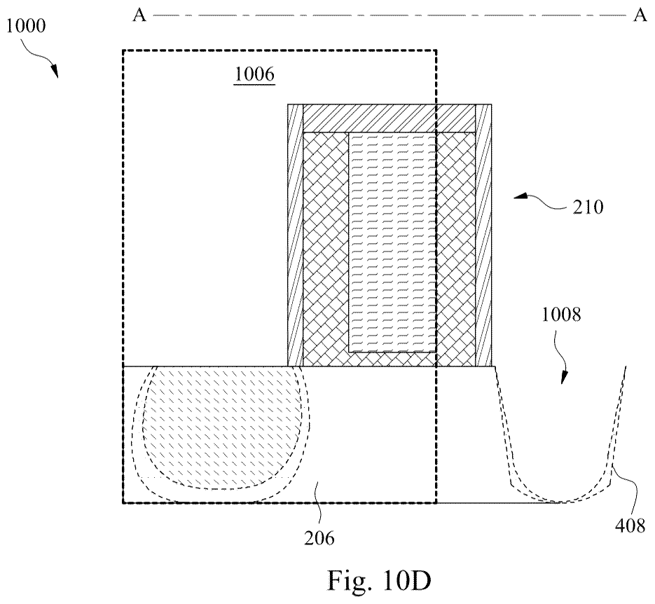

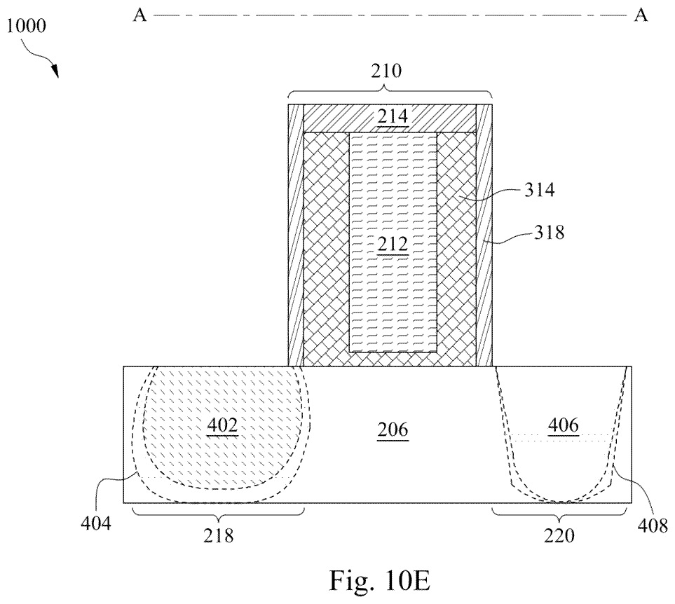

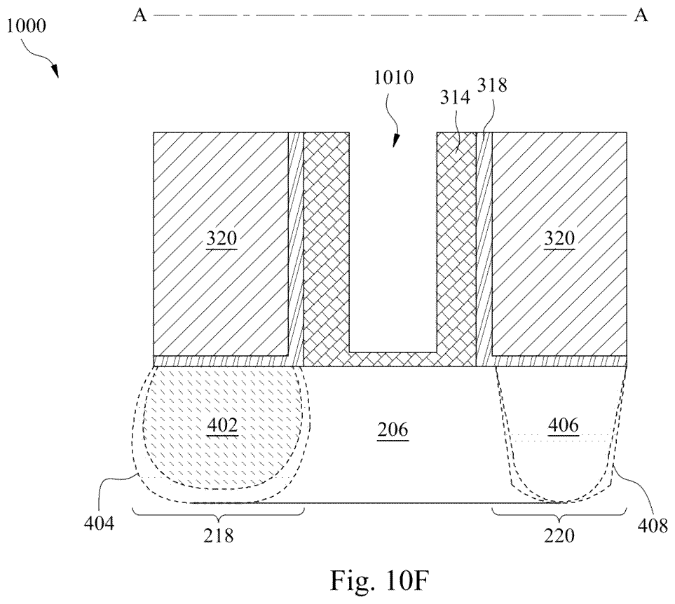

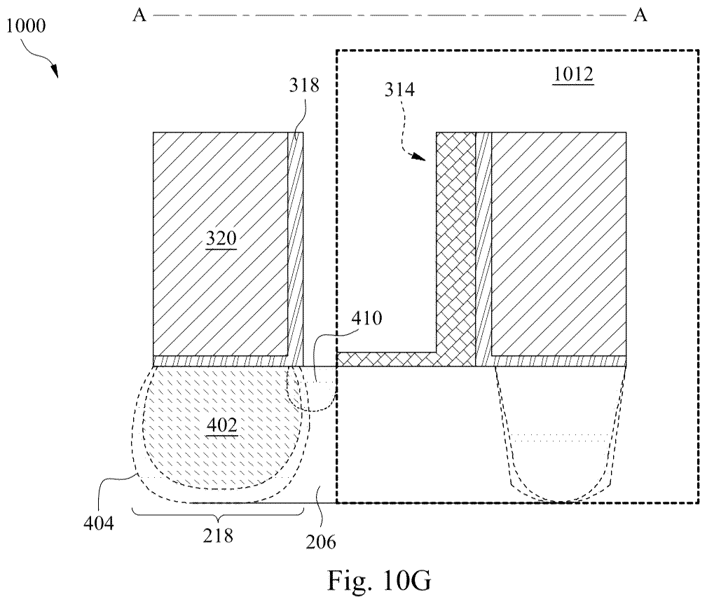

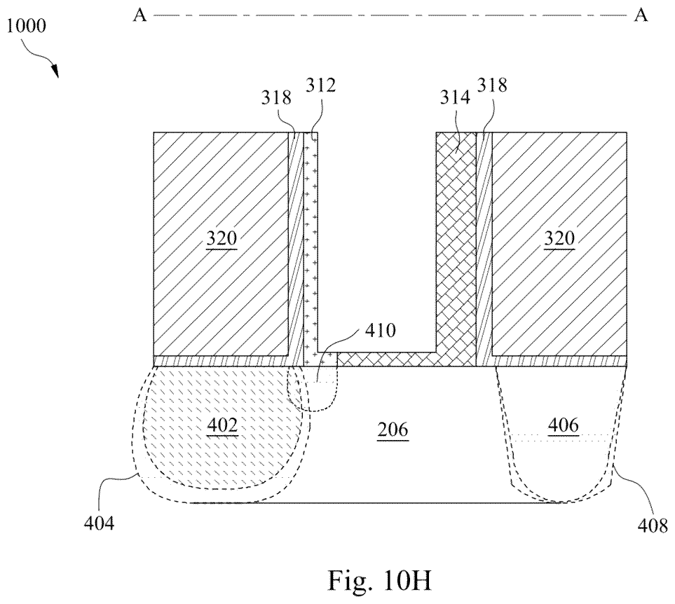

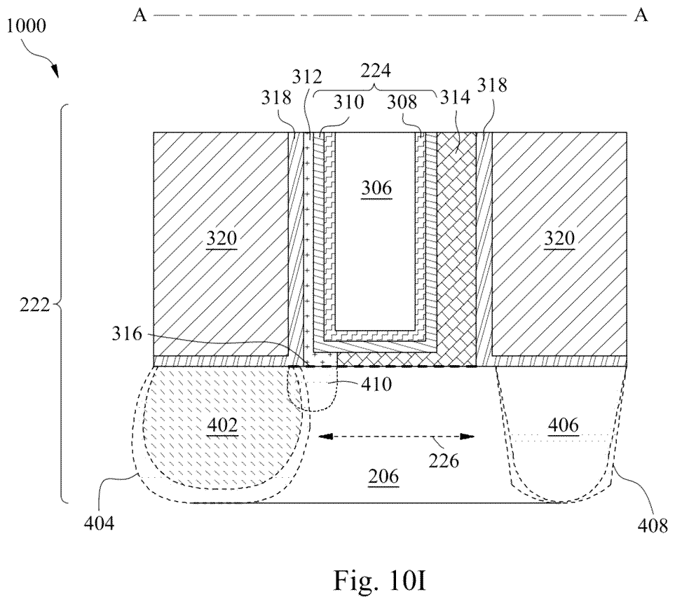

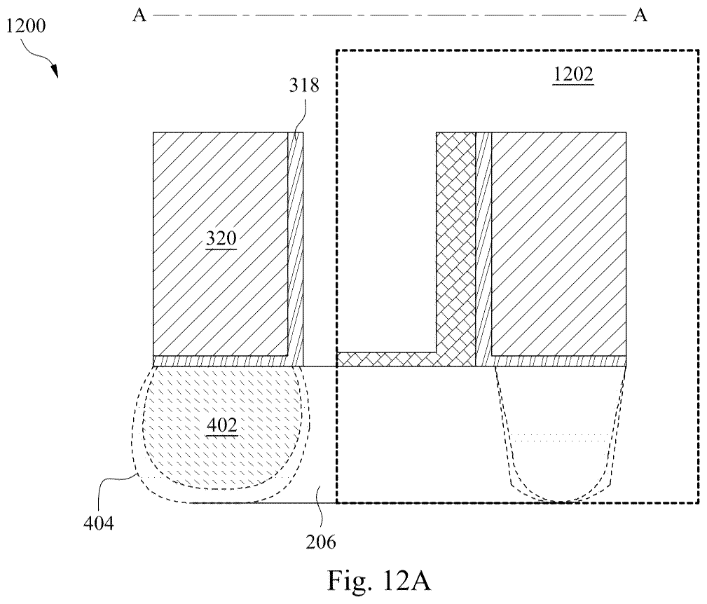

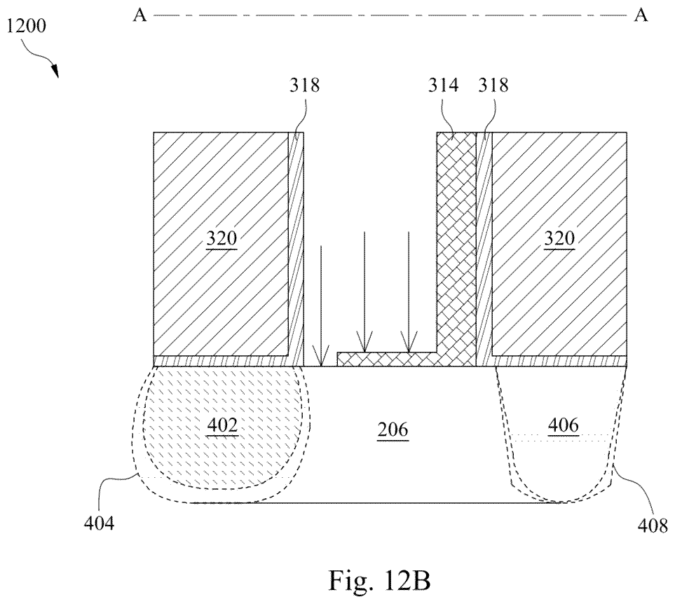

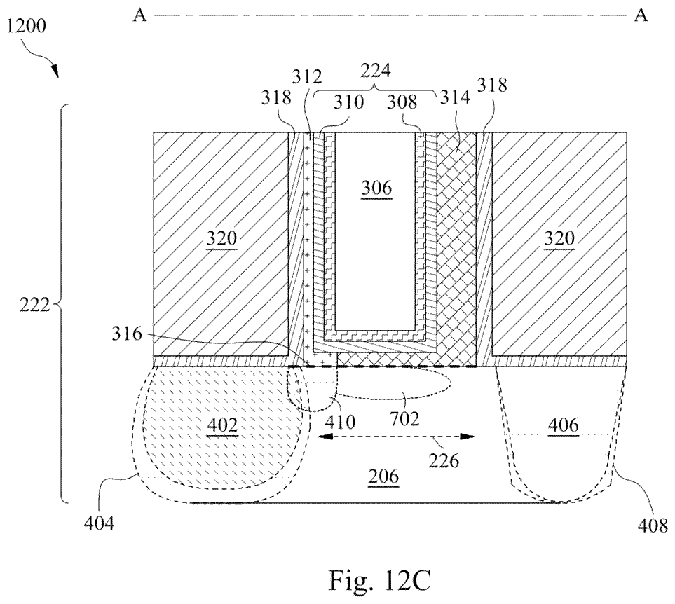

In some implementations and based on techniques described in greater detail in connection with FIGS. 10A-10I, 12A-12C, and elsewhere herein, a width of the overlap region 322 is controlled by one or more semiconductor processing operations that form a profile of doped semiconductor region 302 and/or a profile of the gate structure 224. In contrast to another TFET structure not including such an arrangement, the TFET structure 222 including the overlap region 322 may have an increased threshold voltage at which quantum tunneling begins and the TFET structure 222 conducts current in the channel region 226. Such an increased threshold voltage may reduce a power consumption of the TFET structure 222, increase a switching speed of the TFET structure 222, and/or improve noise margins of the TFET structure 222 to maintain a signal integrity within a semiconductor device including the TFET structure 222, among other examples.

Furthermore, and as shown in the section view C-C, the TFET structure 222 includes an underlap region 324 in which the doped semiconductor region 304 underlaps the gate structure 224 (e.g., no portions of the doped semiconductor region 304 and the gate structure 224 project within a common area). As shown in the section view C-C, a portion of the dielectric layer 314 is within the underlap region 324.

In some implementations and based on techniques described in greater detail in connection with FIGS. 10A-10I, 12A-12C, and elsewhere herein, a width of the underlap region 324 is controlled by one or more semiconductor processing operations that form a profile of the doped semiconductor region 304 and/or an oxidation process used to form the dielectric layer 314. In contrast to another TFET structure not including such an arrangement, the TFET structure 222 including the underlap region 324 may have decreased leakage or flow of electrical current within the TFET structure 222 during an off state. Such a decreased leakage may improve a power efficiency of the TFET structure 222, reduce an amount of heat generated by the TFET structure 222, increase a switching speed of the TFET structure 222, and/or improve a reliability of a semiconductor device including the TFET structure 222, among other examples.

As described in connection with FIGS. 3A and 3B, implementation 300 includes a TFET structure (e.g., the TFET structure 222) having a P-I-N structure that governs charge carrier flow through the channel region 226. In other words, and as an example, the TFET structure 222 includes a P-I junction between the doped semiconductor region 302 (e.g., a P semiconductor region) and the fin structure 206 (e.g., an intrinsic semiconductor region) and an I-N junction between the fin structure and the doped semiconductor region 304 (e.g., an N semiconductor region).

As described in connection with FIGS. 3A and 3B, a structure (e.g., the TFET structure 222) includes a conductive core (e.g., the conductive core 306) of a conductive material. The structure includes a first dielectric sidewall (e.g., the dielectric layer 312) of a first dielectric material along a first side of the conductive core. The structure includes a second dielectric sidewall (e.g., the dielectric layer 314) of a second dielectric material along a second, opposite side of the conductive core, where the second dielectric material is different than the first dielectric material. The structure includes a fin-shaped intrinsic semiconductor region (e.g., the fin structure 206) having an interface region (e.g., the interface region 316) that connects with the first dielectric sidewall and the second dielectric sidewall and that is below the conductive core. The structure includes a first doped semiconductor region (e.g., the doped semiconductor region 302) including a first dopant along a first side of the fin-shaped intrinsic semiconductor region that is proximate to the first dielectric sidewall. The structure includes a second doped semiconductor region (e.g., the doped semiconductor region 304) including a second dopant along a second, opposite side of the fin-shaped intrinsic semiconductor region that is proximate to the second dielectric sidewall, where the second dopant includes a different dopant type than the first dopant.

As indicated above, FIGS. 3A and 3B are provided as an example. Other examples may differ from what is described with regard to FIGS. 3A and 3B.

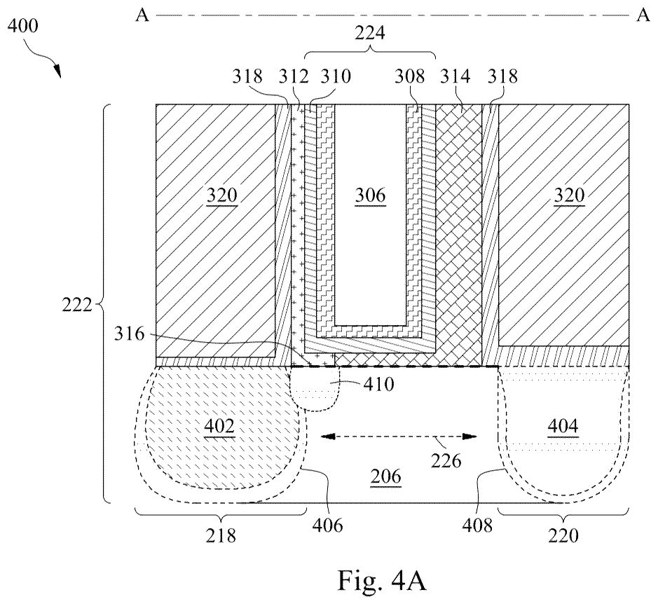

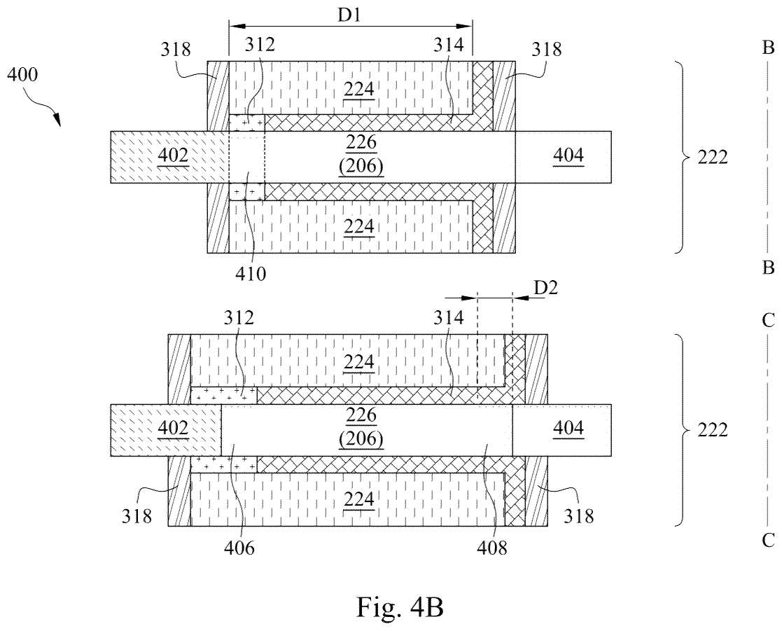

FIGS. 4A and 4B are diagrams of an example implementation 400 described herein. Implementation 400 shows an example of the semiconductor device 200 in which the source region 218 includes a doped semiconductor region 402 and a doped semiconductor region 406. In contrast to the doped semiconductor region 302 that is moderately-doped with a p-type dopant as described in connection with FIGS. 3A and 3B, the doped semiconductor region 402 is heavily-doped with a p-type dopant (e.g., the doped semiconductor region 402 is a P+ semiconductor region that includes a heavy concentration of a p-type dopant as described above). Furthermore, the doped semiconductor region 404 is moderately-doped with an n-type dopant (e.g., the doped semiconductor region 404 is an N semiconductor region that includes a moderate concentration of an n-type dopant as described above).

FIG. 4A shows section view A-A of the TFET structure 222. As shown in FIG. 4A, the source region 218 includes a doped semiconductor region 406 (e.g., a “skirt”) along a perimeter of the doped semiconductor region 402. Furthermore, the doped semiconductor region 406 is moderately-doped with an n-type dopant (e.g., the doped semiconductor region 406 is an N semiconductor region that includes a moderate concentration of an n-type dopant as described above). As the doped semiconductor region 402 includes a p-type dopant and the doped semiconductor region 406 includes an n-type dopant, the source region 218 includes antitype dopants.

Additionally, and as shown, the drain region 220 includes a doped semiconductor region 408 along the perimeter of the doped semiconductor region 404. Furthermore, the doped semiconductor region 408 is lightly-doped with an n-type dopant (e.g., the doped semiconductor region 408 is an N− semiconductor region that includes a moderate concentration of an n-type dopant as described above). As the doped semiconductor region 404 includes an n-type dopant and the doped semiconductor region 408 includes an n-type dopant, the drain region 220 includes same dopant types. Furthermore, as the doped semiconductor region 404 is an N+ semiconductor region and the doped semiconductor region 408 is an N− semiconductor region, the drain region 220 includes a doping gradient.

A ratio of concentrations of dopants in the doped semiconductor regions 404 and 408 may be selected to lower and/or reduce ambipolar current in the TFET structure 222 (e.g., simultaneous flow of electrons and holes). For example, and to reduce and/or lower the ambipolar current in the TFET structure 222, a selected ratio of an n-type dopant in the doped semiconductor region 408 to an n-type dopant in the doped semiconductor region 404 may be included in a range of approximately 1:100 to 50:100. However, other values and ranges for the ratio of concentrations are within the scope of the present disclosure.

As further shown in FIG. 4A, the TFET structure 222 further includes a doped semiconductor region 410 (e.g., a “pocket”) that is proximate the interface region 316 and that is between the doped semiconductor region 402 and the fin structure 206 (e.g., a fin-shaped intrinsic semiconductor region). In some implementations, the doped semiconductor region 410 is heavily doped with an n-type dopant (e.g., the doped semiconductor region 410 is an N+ region that includes a heavy concentration of an n-type dopant as described above).

FIG. 4B shows section view B-B and section view C-C of the TFET structure 222. The section view B-B shows the doped semiconductor region 410. Furthermore, and as shown in section view B-B, the gate structure 224 has a width D1 (e.g., a gate length). The section view C-C shows the doped semiconductor region 402, the doped semiconductor region 404, the doped semiconductor region 406, and the doped semiconductor region 408.

One or more of the dimensions may be interrelated. For example, a width D1 of the gate structure 224 (e.g., a gate length) may be interrelated with a width D2 of the doped semiconductor region 408. In some implementations, values of the interrelated dimensions may be design and/or performance choices. Additionally, or alternatively and as part of miniaturizing the TFET structure 222, one or more scalable ratios of the interrelated dimensions may be governed by process capabilities of the semiconductor processing tools 102-114 as described in connection with FIG. 1 and/or semiconductor manufacturing processing steps as described in greater detail in connection with FIGS. 10A-10I and/or FIGS. 12A-12C.

As an example, a ratio of the width D2 to the width D1 (D2:D1) may be included in a range of approximately 3:10 to approximately 5:10. If the ratio is less than approximately 3:10, an amount of electrical current flowing in the TFET structure 222 during an off state may increase to fail to satisfy a leakage performance threshold. If the ratio D2:D1 is between approximately 3:10 and 5:10, the TFET structure 222 may satisfy the performance threshold and be manufacturable. If the ratio D2:D1 is greater than approximately 5:10, process capabilities of one or more semiconductor processing tools and/or semiconductor manufacturing processing steps may be inadequate to form the gate structure 224. However, other values and ranges for the ratio D2:D1 are within the scope of the present disclosure.

In some implementations, inclusion of the doped semiconductor regions 402 and 406 in the TFET structure 222 promotes vertical tunneling within the channel region 226. In addition to benefits realized through implementation 300 of FIGS. 3A and 3B, vertical tunneling promoted by implementation 400 may further increase a threshold voltage to realize additional reductions in power consumption, increases in switching speeds, and/or improvements in noise margins in a semiconductor device including the TFET structure 222. Furthermore, inclusion of the doped semiconductor regions 404 and 408 in implementation 400 may further reduce leakage in the TFET structure 222 to realize additional improvements in power efficiency, reductions in amounts of heat generated, increases in switching speed, and/or improvements in reliability of the semiconductor device including the TFET structure 222.

As described in connection with FIGS. 4A and 4B, implementation 400 includes a TFET structure (e.g., the TFET structure 222) having a P-N-I-N-N structure that governs charge carrier flow through the channel region 226. In other words, and as an example, the TFET structure 222 includes a P-N junction between the doped semiconductor region 402 (e.g., a P+ semiconductor region) and the doped semiconductor region 406 (e.g., an N semiconductor region), an N-I junction between the doped semiconductor region 406 and the fin structure 206 (an intrinsic semiconductor region), an I-N junction between the fin structure 206 and the doped semiconductor region 408 (e.g., an N− semiconductor region), and an N-N junction between the doped semiconductor region 408 and the doped semiconductor region 404 (e.g., an N+ semiconductor region).

As indicated above, FIGS. 4A and 4B are provided as an example. Other examples may differ from what is described with regard to FIGS. 4A and 4B.

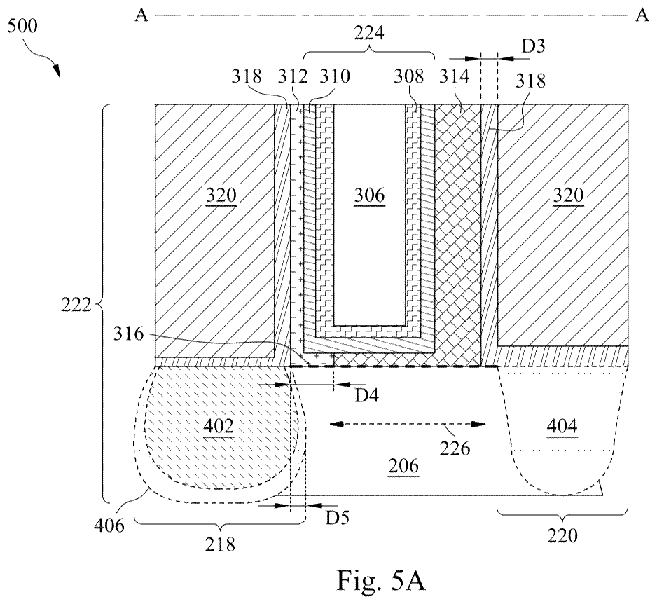

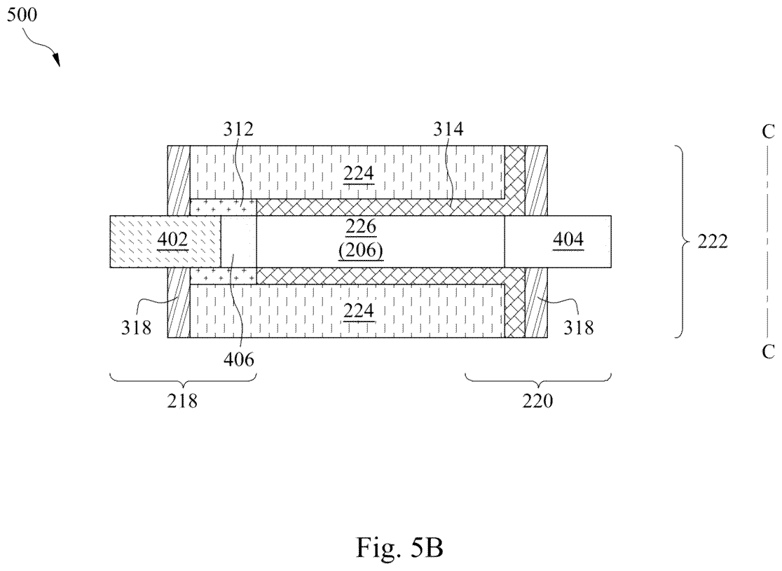

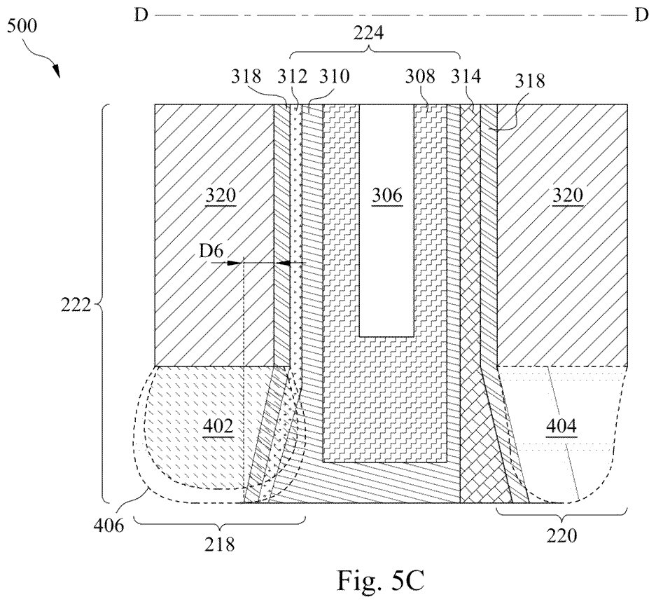

FIGS. 5A-5C are diagrams of an example implementation 500 described herein. Implementation 500 shows an example of the TFET structure 222 in which the source region 218 includes the doped semiconductor region 402 and the doped semiconductor region 406 as described in connection with FIG. 4A, FIG. 4B, and elsewhere herein. Additionally, and as shown, the drain region 220 includes the doped semiconductor region 404 described in connection with FIG. 4A, FIG. 4B, and elsewhere herein. However, the drain region 220 of implementation 500 excludes the doped semiconductor region 408 described in connection with FIGS. 4A and 4B.

FIG. 5A shows section view A-A of the TFET structure 222, including example, interrelated dimensions width D3 (e.g., a width of the sidewall spacer layer 318), width D4 (e.g., a width of the dielectric layer 314 along the interface region 316), and distance D5 (e.g., an overlap distance of the source region 218 as measured from a top of the fin structure 206).

In some implementations, and as part of miniaturizing the TFET structure 222, one or more scalable ratios of the interrelated dimensions may be defined by process capabilities of the semiconductor processing tools 102-114 as described in connection with FIG. 1 and/or semiconductor manufacturing processing steps as described in greater detail in connection with FIGS. 10A-10I and/or 12A-12C. For example, a ratio of the width D4 to the width D3 (D4:D3) may be greater than approximately 3:5. If the ratio D4:D3 is less than approximately 3:5, a process capability of an etch tool (e.g., the etch tool 108 of FIG. 1) and/or a capability of an exposure tool (e.g., the exposure tool 104) may be exceeded and cause manufacturing defects within the TFET structure 222.

Additionally, or alternatively and as another example, a ratio of the distance D5 to the width D3 (D5:D3) may be less than approximately 3:5. If the ratio D5:D3 is greater than approximately 3:5, a process capability of the etch tool may be exceeded and cause manufacturing defects at a top of the fin structure 206 to reduce a quality of the dielectric layer 312 and/or the dielectric layer 314.

Additionally, or alternatively, values of the interrelated dimensions may be design gated by a process and/or process capabilities of one or more semiconductor processing tools (e.g., one or more of the semiconductor processing tools 102-114 as described in connection with FIG. 1). For example, if the distance D3 is selected to be less than zero (e.g., a negative distance), the dielectric layer 318 may fail to perform as a contact etch stop layer (CESL) to be rendered incompatible with a process performed by the one or more semiconductor processing tools forming the TFET structure 222.

The dimensions D3, D4, and D5 are provided as one or more examples. However, other ratios, values, and/or ranges for the dimensions D3, D4, and D5 are within the scope of the present disclosure.

FIG. 5B shows section view C-C of the TFET structure 222. A ratio of concentrations of dopants in the doped semiconductor regions 402 and 406 may be selected to improve tunneling current in the TFET structure 222. For example, and to improve the tunneling current in the TFET structure 222, a selected ratio of a p-type dopant in the doped semiconductor region 402 to an n-type dopant in the doped semiconductor region 406 may be included in a range of approximately 1:10 to approximately 1:1. However, other values and ranges for the ratio of concentrations are within the scope of the present disclosure.

FIG. 5C shows section view D-D of the TFET structure 222 (e.g., a section through the STI region 208 as described in connection with FIG. 2B). As shown in FIG. 5C, a bottom extension length of the gate structure 224 towards the source region 218 includes a width D6.

In some implementations, and as part of miniaturizing the TFET structure 222, one or more scalable ratios of the interrelated dimensions may be defined by process capabilities of the semiconductor processing tools 102-114 as described in connection with FIG. 1 and/or semiconductor manufacturing processing steps as described in greater detail in connection with FIGS. 10A-10I and/or 12A-12C. Additionally, or alternatively, values of the interrelated dimensions may be design and/or performance choices.

For example, and in some implementations, the width D6 is selected such that a ratio of the width D6 to the width D1 (D6:D1) (e.g., a ratio of the width D6 to width of the gate structure 224, or gate length, as described in connection with FIG. 4B) is included in a range of approximately zero to approximately 3:10. Selecting the ratio D6:D1 to be less than approximately zero (e.g., the width D6 is “negative”) may not enable formation of the TFET structure 222 and/or be incompatible with semiconductor manufacturing process flows used to form the TFET structure 222. Selecting the ratio D6:D1 between approximately zero and approximately 3:10 may provide an overlapping of the gate structure 224 and the source region 218 (e.g., the overlap region 322 of FIG. 3B) that enables a threshold voltage performance (e.g., Vₜₕ) and/or an on-current performance (e.g., Iₒₙ) of the TFET structure 222 to satisfy a performance threshold. Selecting the ratio D6:D1 to be greater than approximately 3:10 may reduce overlapping of the gate structure 224 and the source region 218 such that a threshold voltage performance (e.g., Vₜₕ) and/or an on-current performance (e.g., Iₒₙ) of the TFET structure 222 fails to satisfy a performance threshold. However, other values and ranges for the ratio D6:D1 are within the scope of the present disclosure.

As described in connection with FIGS. 5A-5C, implementation 500 includes a TFET structure (e.g., the TFET structure 222) having a P-N-I-N structure that governs charge carrier flow through the channel region 226. In other words, and as an example, the TFET structure 222 includes a P-N junction between the doped semiconductor region 402 (e.g., a P+ semiconductor region) and the doped semiconductor region 406 (e.g., an N semiconductor region), an N-I junction between the doped semiconductor region 406 and the fin structure 206 (an intrinsic semiconductor region), and an I-N junction between the fin structure 206 and the doped semiconductor region 404 (e.g., an N+ semiconductor region).

As indicated above, FIGS. 5A-5C are provided as an example. Other examples may differ from what is described with regard to FIGS. 5A-5C.

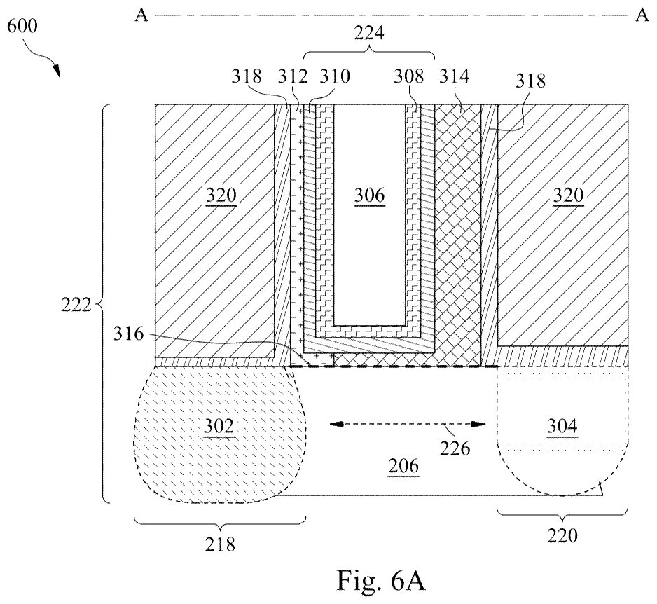

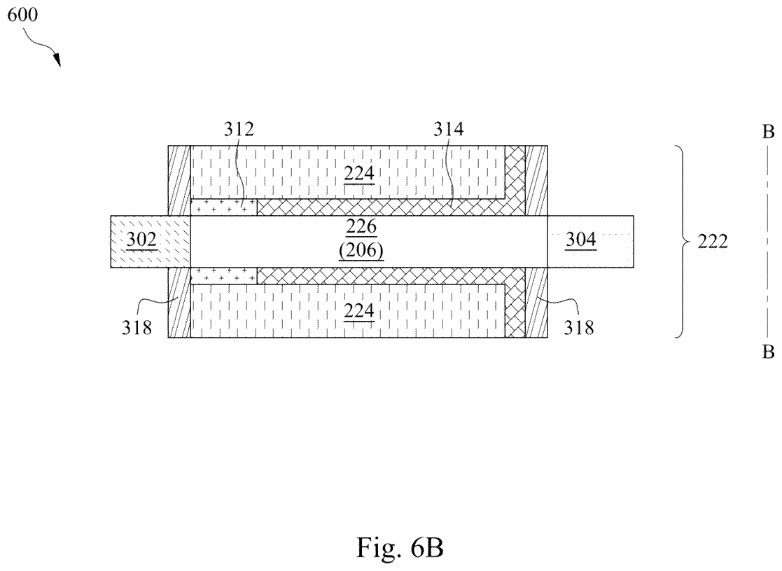

FIGS. 6A and 6B are diagrams of an example implementation 600 described herein. Similar to implementation 300 of FIGS. 3A and 3B, implementation 600 shows an example of the semiconductor device 200 in which the source region 218 includes the doped semiconductor region 302.

In contrast to implementation 300 of FIGS. 3A and 3B, a configuration of the dielectric layer 312 and the dielectric layer 314 on the interface region 316 has changed (e.g., in implementation 600, a width of the dielectric layer 312 has been reduced and a width of the dielectric layer 314 has been increased).

In some implementations, changes to the configurations of the dielectric layer 312 and/or 314 on the interface region 316 (e.g., changes to widths of the dielectric layer 312 and/or 314 on the interface region) are used to fine tune performance characteristics of the TFET structure 222 having the source region 218 and the drain region 220 that are asymmetrically doped (e.g., that include the doped semiconductor regions 302 and 304 having different dopant types).

As indicated above, FIGS. 6A and 6B are provided as an example. Other examples may differ from what is described with regard to FIGS. 6A and 6B.

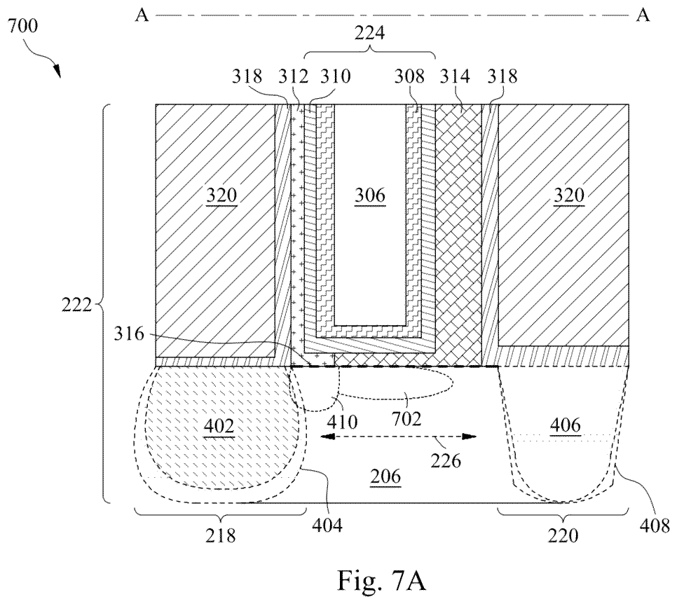

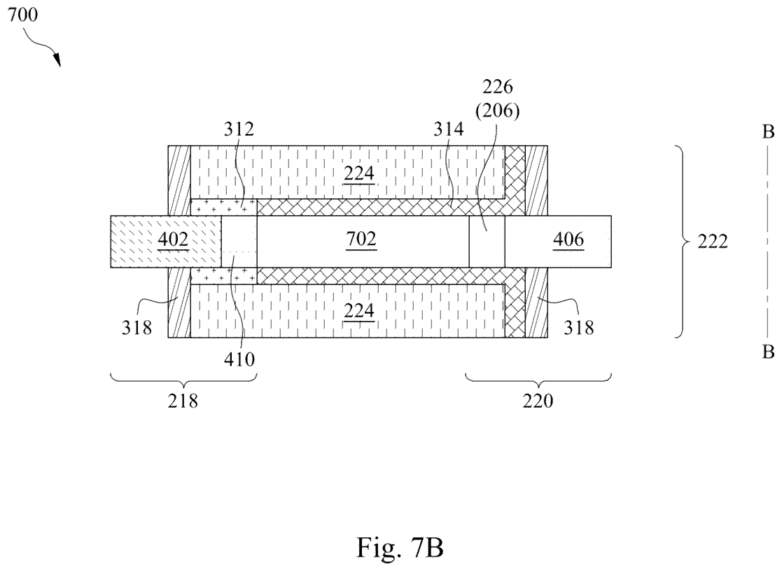

FIGS. 7A and 7B are diagrams of an example implementation 700 described herein. In addition to features described in connection with FIG. 4A, FIG. 4B, and elsewhere herein, implementation 700 includes a doped semiconductor region 702 proximate a top of the fin structure 206. In other words, the channel region 226 includes a wider doping region (e.g., the doped semiconductor region 410 plus the doped semiconductor region 702).

As shown in FIG. 7A, the doped semiconductor region 702 is proximate the interface region 316. Additionally, or alternatively, the doped semiconductor region 702 is adjacent to the doped semiconductor region 410. Additionally, or alternatively, the doped semiconductor region 702 is between the doped semiconductor region 402 and the doped semiconductor region 406. In some implementations, the doped semiconductor region 702 is lightly-doped with an n-type dopant (e.g., the doped semiconductor region 702 is an N− semiconductor region that includes a moderate concentration of an n-type dopant as described above).

As shown in FIG. 7B, the doped semiconductor region 702 is adjacent to an intrinsic semiconductor region (e.g., an undoped region) that is part of the fin structure 206. To reduce an electrical resistance of the channel region 226 and improve a performance of the TFET structure 222, a selected ratio of an n-type dopant in the doped semiconductor region 702 to an n-type dopant in the doped semiconductor region 410 may be included in a range of approximately 3:10 to approximately 8:10. However, other values and ranges for the ratio of concentrations are within the scope of the present disclosure.

As indicated above, FIGS. 7A and 7B are provided as an example. Other examples may differ from what is described with regard to FIGS. 7A and 7B.

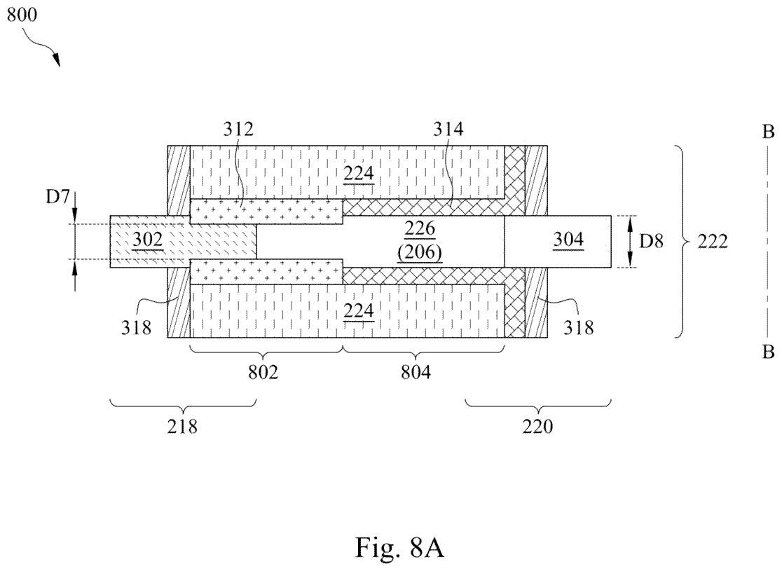

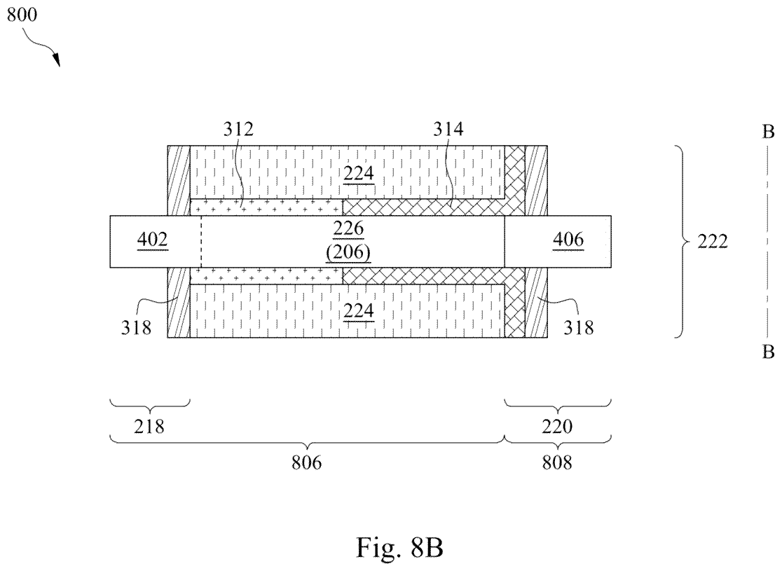

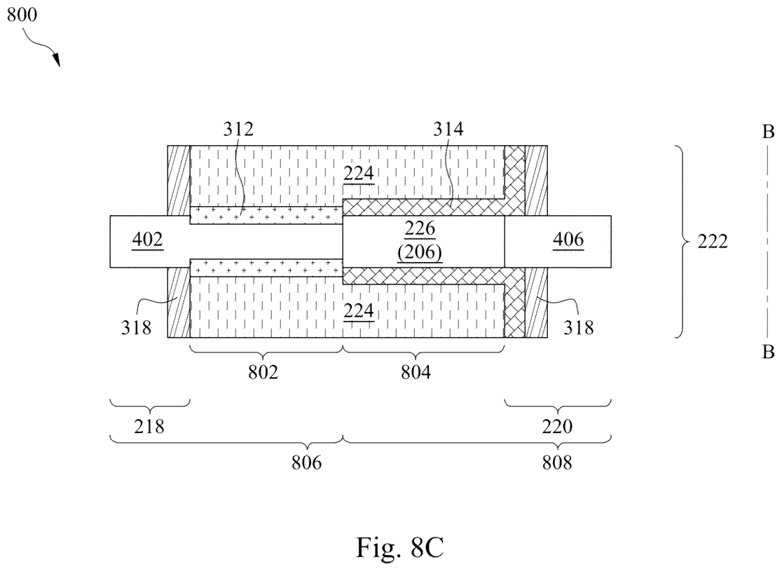

FIGS. 8A-8C are diagrams of an example implementation 800 described herein. In contrast to aspects of the channel region 226 described in connection with FIGS. 3A-7B, the channel region 226 includes portions having different widths and/or materials having different band gap materials.

FIG. 8A shows an example of the channel region 226 including portions having different widths. As shown in section view B-B of FIG. 8A, the channel region 226 includes a portion 802 that is proximate the source region 218 and a portion 804 that is proximate the drain region 220. In some implementations, the portion 802 and the portion 804 include a same semiconductor material (e.g., silicon (Si)).

The portion 802 may have a thickness D7 that is reduced relative to a thickness D8 of the portion 804. By having the thickness D7 that is reduced relative to the thickness D8, an electrical field across the channel region 226 may have a gradient (e.g., an electrical potential proximate the source region 218 may be increased relative to an electrical potential proximate the drain region 220). Such a gradient may increase a probability of tunneling of charge carriers from the source region 218 into the channel region 226 (e.g., increase a saturation-current (Isat) of the TFET structure 222), thereby increasing a speed performance a semiconductor device including the TFET structure 222. Furthermore, such a gradient may decrease a probability of tunneling of charge carriers from the drain region 220 into the channel region 226, thereby decreasing leakage within the TFET structure 222. Such a decreased leakage may improve a power efficiency of the TFET structure 222, reduce an amount of heat generated by the TFET structure 222, increase a switching speed of the TFET structure 222, and/or improve a reliability of a semiconductor device including the TFET structure 222, among other examples.

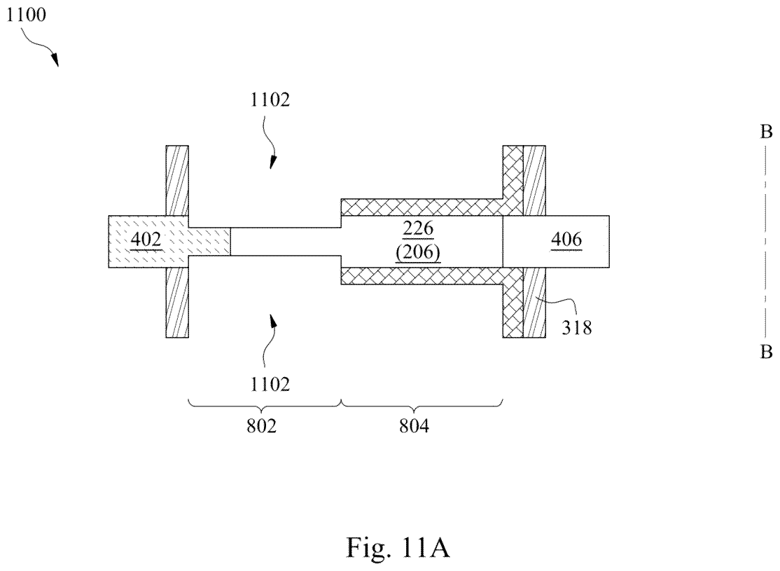

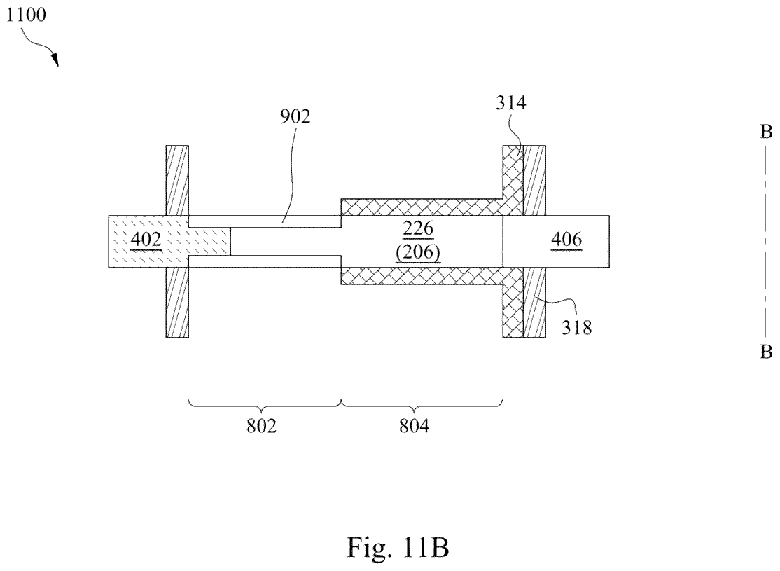

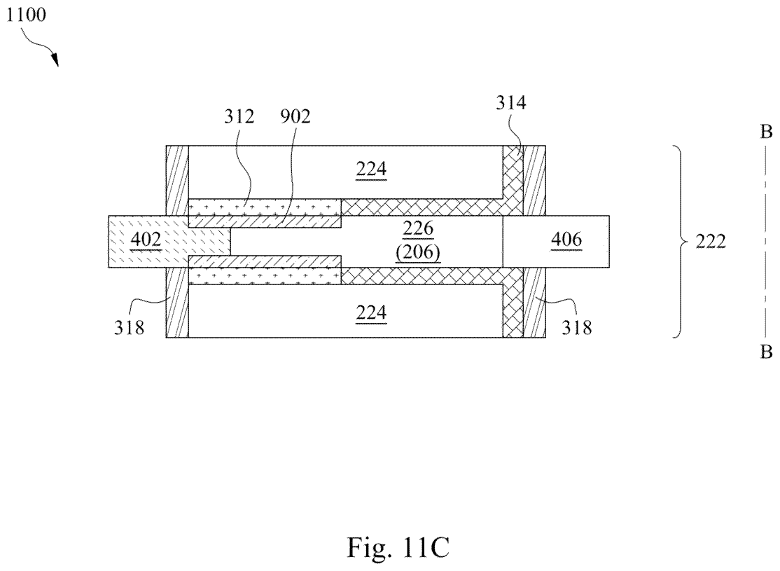

In some implementations, and as part of miniaturizing the TFET structure 222, a scalable ratio of the thicknesses D7:D8 may be defined by process capabilities of the semiconductor processing tools 102-114 as described in connection with FIG. 1 and/or semiconductor manufacturing processing steps as described in greater detail in connection with FIGS. 11A-11C. Additionally, or alternatively, the scalable ratio of the thicknesses D7:D8 may be selected based on a desired gradient of the electrical potential across the channel region 226.

As an example, and in some implementations, the ratio D7:D8 may be less than approximately 8:10. If the ratio D7:D8 is greater than approximately 8:10, a variation in the electrical potential across the channel region 226 (e.g., the gradient) may not be sufficient to increase a probability of tunneling of charge carriers from the source region 218 to the channel region 226 and reduce a probability of charge carriers tunneling from the drain region 220 into the channel region 226. If the ratio D7:D8 is less than approximately 8:10, the variation in the electrical potential across the channel region 226 may be sufficient to increase the probability of the tunneling of charge carriers from the source region 218 into the channel region 226 and reduce the probability of the tunneling of the charge carriers from the drain region 220 into the channel region 226.

Additionally, or alternatively, the thickness D7 may be greater than approximately 2 nanometers (nm). Selecting the thickness D7 to be less than approximately 2 nanometers may reduce an amount of silicon supplying atoms as a carrier source to degrade a mobility of charge carriers within the TFET structure 222. Selecting the thickness to be greater than approximately 2 nanometers may provide a sufficient amount of silicon for supplying atoms as a carrier source to support a needed mobility of charge carriers within the TFET structure 222.

Values and ratios related to the thicknesses D7 and D8 are provided as an example. However, other values and ratios related to the thicknesses D7 and D8 are within the scope of the present disclosure.

FIG. 8B shows an example in which portions of the TFET structure 222 include different band gap materials. As shown in the section view B-B of FIG. 8B, a portion 806 of the TFET structure 222 (e.g., a portion including the source region 218 and the channel region 226) includes a low band gap material, and a portion 808 of the TFET structure 222 (e.g., a portion including the underlap region 324) includes a high band gap material. The low band gap material of portion 806 may include germanium (Ge), silicon germanium (SiGe), indium antimonide (InSb), indium arsenide (InAs), or gallium antimonide (GaSb), among other examples. The high band gap material of portion 808 may include silicon (Si), indium phosphide (InP), gallium phosphide (GaP), or gallium arsenide (GaAs), among other examples.

A difference in energy levels at an interface between the portion 806 and the portion 808 may develop an energy barrier that reduces a probability of tunneling of charge carriers from the drain region 220 into the channel region 226 is, thereby decreasing leakage within the TFET structure 222. Such a decreased leakage may improve a power efficiency of the TFET structure 222, reduce an amount of heat generated by the TFET structure 222, increase a switching speed of the TFET structure 222, and/or improve a reliability of a semiconductor device including the TFET structure 222, among other examples.

FIG. 8C shows an example of the TFET structure 222 that combines portions having different widths and materials having different band gap materials as described in connection with FIGS. 8A and 8B. Furthermore, the TFET structure 222 of FIG. 8C may combine one or more features described in connection with FIGS. 8A and 8B. As such, the TFET structure 222 as shown in FIG. 8C may realize combined performance benefits as described in connection with FIGS. 8A and 8B.

As described in connection with FIGS. 2A-8C, and in some implementations, a semiconductor device (e.g., the semiconductor device 200) includes a tunneling fin-based transistor (e.g., the TFET structure 222) that includes a gate structure (e.g., the gate structure 224), a source region (e.g., the source region 218) below the gate structure and proximate to a first side of the gate structure, a drain region (e.g., the drain region 220) below the gate structure and proximate to a second, opposite side of the gate structure, and a channel region (e.g., the channel region 226) between the source region and the drain region. The channel region includes a first portion having a first thickness (e.g., the portion 802 having the thickness D7) near the source region and a second portion having a second thickness (e.g., the portion having the thickness D8) near the drain region, where the second thickness is different from the first thickness.

As indicated above, FIGS. 8A-8C are provided as an example. Other examples may differ from what is described with regard to FIGS. 8A-8C.

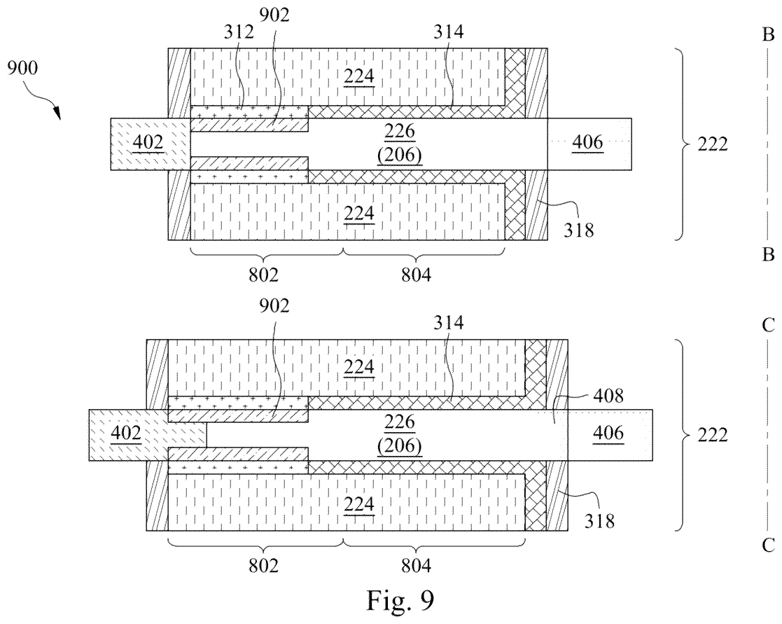

FIG. 9 is a diagram of an example implementation 900 described herein. In addition to including features described in connection with FIG. 4A, FIG. 4B, and elsewhere herein, the TFET structure 222 of implementation 900 includes a doped semiconductor region 902 (e.g., a capping layer) between the dielectric layer 312 and the portion 802 of the channel region 226.

Section views B-B and C-C of FIG. 9 show the doped semiconductor region 902. In some implementations, the doped semiconductor region 902 is lightly-doped with an n-type dopant (e.g., the doped semiconductor region 902 is an N− semiconductor region that includes a moderate concentration of an n-type dopant as described above). In some implementations, the doped semiconductor region 902 increases a likelihood of vertical tunneling of charge carriers within the TFET structure 222 to further improve a threshold voltage performance (e.g., Vₜₕ) and/or an on-current performance (e.g., Iₒₙ) of the TFET structure 222.

The doped semiconductor region 902 includes a high band gap material. Furthermore, and as described in greater detail in connection with FIGS. 11A-11C, the doped semiconductor region 902 may be a regrowth layer that is epitaxially grown on the portion 802.

The high band gap material may include silicon (Si), indium phosphide (InP), gallium phosphide (GaP), or gallium arsenide (GaAs), among other examples. In some implementations, the doped semiconductor region 902 and the channel region 226 (e.g., the fin structure 206) include a same high band gap material. Alternatively, and in some implementations, the doped semiconductor region 902 and the channel region 226 include different high band gap materials.

As indicated above, FIG. 9 is provided as an example. Other examples may differ from what is described with regards to FIG. 9.

FIGS. 2A-9 describe different implementations of the semiconductor device 200 including TFET structure 222. The TFET structure 222 may include a combination of two or more doped semiconductor regions (e.g., a combination of two or more of the doped semiconductor region 404, 406, 408, 410, 702, and/or 902) having a same n-type dopant (e.g., a same electron-rich dopant). In some implementations, two or more of the doped semiconductor regions 404, 406, 408, 410, 702, and/or 902 share a same n-type dopant (e.g., a same chemical element such as phosphorous (P), arsenic (As), and/or antimony (Sb)). Conversely, and in some implementations, two or more of the doped semiconductor regions 404, 406, 408, 410, 702, and/or 902 have a different n-type dopant (e.g., different electron-rich dopants). Furthermore, and as described in connection with FIGS. 2A-9, concentrations of the n-type dopant may vary in each of the doped semiconductor regions 404, 406, 408, 410, 702, and/or 902.

Additionally, the TFET structure 222 may have at least one doped semiconductor region having a p-type dopant (e.g., the doped semiconductor region 302 and/or the doped semiconductor region 402). Furthermore, a channel region of the TFET structure 222 (e.g., the channel region 226 in the fin structure 206) may include portions having different widths (e.g., the portion 802 and the portion 804) and/or including different combinations of materials.

In this way, and using different combinations of features described in connection with FIGS. 2A-9, a performance of the TFET structure 222 may be increased and/or tuned to such that a threshold voltage performance (e.g., Vₜₕ) of the TFET structure 222 is compatible with an available power supply in the semiconductor device 200. Furthermore, leakage in the semiconductor device 200 may be reduced.

FIGS. 10A-10I are diagrams of example series of semiconductor manufacturing operations 1000 used to form one or more portions of a semiconductor device (e.g., the semiconductor device 200) including a transistor structure. One or more portions of the transistor structure may correspond the TFET structure 222 of implementation 700 as described in connection with FIGS. 7A and 7B. Furthermore, and in some implementations, one or more of the semiconductor processing tools 102-114 described in connection with FIG. 1 performs one or more of the semiconductor manufacturing operations 1000.

As shown in FIG. 10A, the series of semiconductor manufacturing operations 1000 includes forming the dummy gate structure 210 on and/or over the fin structure 206. As part of forming the dummy gate structure 210, a deposition tool 102, an exposure tool 104, a developer tool 106, a etch tool 108, a planarization tool 110, and/or a plating tool 112 may be used to perform a combination of operations described in connection with FIG. 1 to form the dielectric layer 314, the gate electrode layer 212, the hard mask layer 214, and/or the sidewall spacer layer 318.

As shown in FIG. 10B, and as part of forming a source region (e.g., the source region 218) the series of semiconductor manufacturing operations 1000 includes forming the doped semiconductor region 404. As part of forming the doped semiconductor region 404, a mask 1004 is formed that masks portions of the dummy gate structure 210 and/or the fin structure 206. As an example, a deposition tool 102 may be used to form a photoresist layer over and/or on the dummy gate structure 210 and the fin structure 206. An exposure tool 104 may be used to expose the photoresist layer to a radiation source to pattern the photoresist layer. A developer tool 106 may be used to develop and remove portions of the photoresist layer to expose the mask 1004.

Furthermore, and as part of forming the doped semiconductor region 404, a cavity 1002 is formed in the fin structure 206. In some implementations, a pattern in a photoresist layer is used to etch the fin structure 206 to form the cavity 1002. In these implementations, a deposition tool 102 may be used to form the photoresist layer over and/or on the fin structure 206. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the fin structure 206 based on the pattern to form the cavity 1002 in the fin structure 206. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the fin structure 206 based on a pattern.

Furthermore, and as part of forming the doped semiconductor region 404, an ion implantation tool 114 may be used to perform an ion implantation operation that implants ions of an n-type dopant below a surface of the cavity 1002. In some implementations, the ion implantation operation implants a moderate concentration of the n-type dopant.

As shown in FIG. 10C, the series of semiconductor manufacturing operations 1000 includes forming the doped semiconductor region 402. In some implementations, a deposition tool 102 is used to form a semiconductor material in the cavity 1002 in an epitaxial growth operation. Alternatively, a deposition tool 102 may be used to form a semiconductor material in the cavity 1002 using a PVD operation, an ALD operation, a CVD operation, an oxidation operation, another type of deposition operation described in connection with FIG. 1, and/or another suitable deposition operation.

Furthermore, and as part of forming the doped semiconductor region 404, an ion implantation tool 114 may be used to perform an ion implantation operation that implants ions of a p-type dopant in the semiconductor material. In some implementations, the ion implantation operation implants a heavy concentration of the p-type dopant.

As shown in FIG. 10D, the series of semiconductor manufacturing operations 1000 includes forming the doped semiconductor region 408. As part of forming the doped semiconductor region 408, a mask 1006 is formed that masks portions of the dummy gate structure 210 and/or the fin structure 206. As an example, a deposition tool 102 may be used to form a photoresist layer over and/or on the dummy gate structure 210 and the fin structure 206. An exposure tool 104 may be used to expose the photoresist layer to a radiation source to pattern the photoresist layer. A developer tool 106 may be used to develop and remove portions of the photoresist layer to expose the mask 1006.

Furthermore, and as part of forming the doped semiconductor region 408, a cavity 1008 is formed in the fin structure 206. In some implementations, a pattern in a photoresist layer is used to etch the fin structure 206 to form the cavity 1002. In these implementations, a deposition tool 102 may be used to form the photoresist layer over and/or on the fin structure 206. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the fin structure 206 based on the pattern to form the cavity 1002 in the fin structure 206. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the fin structure 206 based on a pattern.

Furthermore, and as part of forming the doped semiconductor region 408, an ion implantation tool 114 may be used to perform an ion implantation operation that implants ions of an n-type dopant below a surface of the cavity 1008. In some implementations, the ion implantation operation implants a light concentration of the n-type dopant.

As shown in FIG. 10E, the series of semiconductor manufacturing operations 1000 includes forming the doped semiconductor region 406. In some implementations, a deposition tool 102 is used to form a semiconductor material in the cavity 1008 in an epitaxial growth operation. Alternatively, a deposition tool 102 may be used to form a semiconductor material in the cavity 1008 using a PVD operation, an ALD operation, a CVD operation, an oxidation operation, another type of deposition operation described in connection with FIG. 1, and/or another suitable deposition operation.

Furthermore, and as part of forming the doped semiconductor region 406, an ion implantation tool 114 may be used to perform an ion implantation operation that implants ions of an n-type dopant in the semiconductor material. In some implementations, the ion implantation operation implants a heavy concentration of the n-type dopant.

As shown in FIG. 10F, the series of semiconductor manufacturing operations 1000 includes forming the dielectric layer 320 on and/or over the fin structure 206. As part of forming the dielectric layer 320, a deposition tool 102 may be used to deposit the dielectric layer 320 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric layer 320 after the dielectric layer 320 is deposited.

Furthermore, and as shown in FIG. 10F, the series of semiconductor manufacturing operations 1000 includes performing a gate replacement process that includes removing the hard mask layer 214 and the gate electrode layer 212 to form a cavity 1010 in the dielectric layer 314. In some implementations, a pattern in a photoresist layer is used to etch (e.g., remove) the hard mask layer 214 and/or the gate electrode layer 212 to form the cavity 1010. In these implementations, a deposition tool 102 may be used to form the photoresist layer over and/or on the dielectric layer 314, the sidewall spacer layer 318, and/or the dielectric layer 320. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the hard mask layer 214 and/or the gate electrode layer 212 based on the pattern to form the cavity 1010 in the dielectric layer 314. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the hard mask layer 214 and/or the gate electrode layer 212 based on a pattern.

As shown in FIG. 10G, the series of semiconductor manufacturing operations 1000 includes forming the doped semiconductor region 410. As part of forming the doped semiconductor region 410, a mask 1012 is formed that masks portions of the fin structure 206, the dielectric layer 314, the sidewall spacer layer 318, and/or the dielectric layer 320. As an example, a deposition tool 102 may be used to form a photoresist layer over and/or on portions of the fin structure 206, the dielectric layer 314, the sidewall spacer layer 318, and/or the dielectric layer 320. An exposure tool 104 may be used to expose the photoresist layer to a radiation source to pattern the photoresist layer. A developer tool 106 may be used to develop and remove portions of the photoresist layer to expose the mask 1012.

Furthermore, and as shown in FIG. 10G and as part of the series of semiconductor manufacturing operations 1000, a portion of the dielectric layer 314 is removed to expose a portion of the fin structure 206. As an example, and in some implementations, an etch tool 108 may be used to perform an etch operation that removes the portion of the dielectric layer 314 to expose the portion of the fin structure 206. In some implementations, the etch operation includes a plasma etch operation, a wet chemical etch operation, and/or another type of etch operation.

Furthermore, and as part of forming the doped semiconductor region 410, an ion implantation tool 114 may be used to perform an ion implantation operation that implants ions of an n-type dopant in the exposed portion of the fin structure 206. In some implementations, the ion implantation operation implants a heavy concentration of the n-type dopant.

As shown in FIG. 10H, the series of semiconductor manufacturing operations 1000 includes forming the dielectric layer 312 over and/or on the doped semiconductor region 410 and along the sidewall spacer layer 318. As part of forming the dielectric layer 312, a deposition tool 102 may be used to deposit the dielectric layer 312 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric layer 312 after the dielectric layer 312 is deposited.

As shown in FIG. 10I, the series of semiconductor manufacturing operations 1000 includes forming the gate structure 224 over and/or on the dielectric layer 312 and the dielectric layer 314. As part of forming the gate structure 224, a deposition tool 102 may be used to deposit the conductive layer 310, the conductive layer 308, and/or the conductive core 306 in a CVD operation, a PVD operation, an ALD operation, an electroplating operation, another deposition operation described above in connection with FIG. 1, and/or another suitable deposition operation. In some implementations, a seed layer is deposited prior to deposition of conductive layer 310, the conductive layer 308, and/or the conductive core 306. In some implementations, a planarization tool 110 may be used to planarize the conductive layer 310, the conductive layer 308, and/or the conductive core 306 after the conductive layer 310, the conductive layer 308, and/or the conductive core 306 is deposited.

Although the series of semiconductor manufacturing operations 1000 of FIGS. 10A-10I describe a configuration in which the source region 218 and the drain region 220 of the TFET structure 222 include specific dopant configurations, the configurations are by way of example only, and “opposite” configurations may exist. For example, a similar series of operations may be performed as part of forming a configuration of the TFET structure 222 in which the doped semiconductor region 402 includes an n-type dopant, the doped semiconductor region 404 includes a p-type dopant, and the doped semiconductor region 410 includes a p-type dopant. Additionally, or alternatively, a similar series of operations may be performed as part of forming a configuration of the TFET structure 222 in which the doped semiconductor region 406 includes a p-type dopant and the doped semiconductor region 408 includes a p-type dopant.

As indicated above, FIGS. 10A-10I are provided as an example. Other examples may differ from what is describe with regards to FIGS. 10A-10I.

FIGS. 11A-11C are diagrams of example series of semiconductor manufacturing operations 1100 used to form one or more portions of a semiconductor device (e.g., the semiconductor device 200) including a transistor structure described herein. One or more portions of the transistor structure may correspond to the TFET structure 222 of implementation 800 as described in connection with FIGS. 8A-8C. Additionally, or alternatively, one or more portions of the transistor structure may correspond to the TFET structure 222 of implementation 900 as described in connection with FIG. 9. In some implementations, one or more of the semiconductor processing tools 102-114 described in connection with FIG. 1 performs one or more of the series of semiconductor manufacturing operations 1100.

As shown in FIG. 11A, the series of semiconductor manufacturing operations 1100 includes forming the portion 802 of the fin structure 206. Forming the portion 802 may include, for example, using selective etching to trim the fin structure 206 and form cavities 1102 on opposing sides of the fin structure 206 for regrowth purposes. In these implementations, the deposition tool 102 may be used to form a photoresist layer on the fin structure 206. The exposure tool 104 may be used to expose the photoresist layer to a radiation source to pattern the photoresist layer. The developer tool 106 may be used to develop and remove portions of the photoresist layer to expose the pattern. The etch tool 108 may be used to selectively etch the fin structure 206 based on the pattern to form the cavities 1102 in the fin structure 206. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the fin structure 206 based on a pattern.

As shown in FIG. 11B, the series of semiconductor manufacturing operations 1100 includes forming the doped semiconductor region 902 (e.g., a capping layer). In some implementations, and as part of forming the doped semiconductor region 902, a deposition tool 102 is used to form a semiconductor material in the cavities 1102 in an epitaxial growth operation. Alternatively, a deposition tool 102 may be used to form a semiconductor material in the cavities 1102 using a PVD operation, an ALD operation, a CVD operation, an oxidation operation, another type of deposition operation described in connection with FIG. 1, and/or another suitable deposition operation.

In some implementations, forming a semiconductor material in the cavities 1102 includes a deposition tool 102 directly forming the doped semiconductor region 902 by depositing a semiconductor material that includes a heavy concentration of the n-type dopant.

Alternatively, and in some implementations, forming the semiconductor material in the cavities 1102 includes a deposition tool 102 forming an intrinsic (e.g., undoped) semiconductor material in the cavities 1102. In such implementations, and after forming the semiconductor material in the cavities 1102 by the deposition tool 102, an ion implantation tool 114 may be used to perform an ion implantation operation that implants ions of an n-type dopant in the intrinsic semiconductor material as part of forming the doped semiconductor region 902. In some implementations, the ion implantation operation implants a heavy concentration of the n-type dopant.

As shown in FIG. 11C, the series of semiconductor manufacturing operations 1100 includes forming the dielectric layer 312 over and/or on the doped semiconductor region 902. As an example, and in some implementations, a deposition tool 102 may be used to deposit the dielectric layer 312 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric layer 312 after the dielectric layer 312 is deposited.

As further shown in FIG. 11C, the series of semiconductor manufacturing operations 1100 includes forming the gate structure 224 over and/or on the dielectric layer 312 and the dielectric layer 314. As part of forming the gate structure 224, a deposition tool 102 may be used to deposit one or more conductive layers (e.g., the conductive layer 310, the conductive layer 308, and/or the conductive core 306) in a CVD operation, a PVD operation, an ALD operation, an electroplating operation, another deposition operation described above in connection with FIG. 1, and/or another suitable deposition operation. In some implementations, a seed layer is deposited prior to deposition of the one or more conductive layers. In some implementations, a planarization tool 110 may be used to planarize the one or more conductive layers after the one or more conductive layers are deposited.

As indicated above, FIGS. 11A-11C are provided as an example. Other examples may differ from what is describe with regards to FIGS. 11A-11C.

FIGS. 12A-12C are diagrams of example series of semiconductor manufacturing operations 1200 used to form one or more portions of a semiconductor device (e.g., the semiconductor device 200) including a transistor structure described herein. One or more portions of the transistor structure may correspond to the TFET structure 222 of implementation 700 as described in connection with FIG. 7A and FIG. 7B. In some implementations, one or more of the semiconductor processing tools 102-114 described in connection with FIG. 1 performs one or more of the series of semiconductor manufacturing operations 1200.

As shown in FIG. 12A, the series of semiconductor manufacturing operations 1200 includes forming a mask 1202 that masks portions of the fin structure 206, the dielectric layer 314, the sidewall spacer layer 318, and/or the dielectric layer 320. As an example, a deposition tool 102 may be used to form a photoresist layer over and/or on portions of the fin structure 206, the dielectric layer 314, the sidewall spacer layer 318, and/or the dielectric layer 320. An exposure tool 104 may be used to expose the photoresist layer to a radiation source to pattern the photoresist layer. A developer tool 106 may be used to develop and remove portions of the photoresist layer to expose the mask 1012.

Furthermore, and as shown in FIG. 12A and as part of the series of semiconductor manufacturing operations 1200, a portion of the dielectric layer 314 is removed to expose a portion of the fin structure 206. As an example, and in some implementations, an etch tool 108 may be used to perform an etch operation that removes the portion of the dielectric layer 314 to expose the portion of the fin structure 206. In some implementations, the etch operation includes a plasma etch operation, a wet chemical etch operation, and/or another type of etch operation.

As shown in FIG. 12B, the series of semiconductor manufacturing operations 1200 includes an implant operation (e.g., an implant operation to form the doped semiconductor regions 410 and 702 as described in connection with FIGS. 7A and 7B). As part of the implant operation, an ion implantation tool 114 may be used to perform an ion implantation operation that implants ions of an n-type dopant directly into the exposed portion of the fin structure 206 and through the dielectric layer 314. In some implementations, the dielectric layer 314 alters a concentration of the n-type dopant across the fin structure 206 (e.g., allow a heavier concentration of the n-type dopant in the exposed portion of the fin structure 206 and a lighter concentration of the n-type dopant in the portion of the fin structure 206 directly below the dielectric layer 314.

As shown in FIG. 12C, the series of semiconductor manufacturing operations 1200 includes forming the dielectric layer 312 over and/or on the doped semiconductor region 410 and along the sidewall spacer layer 318. As part of forming the dielectric layer 312, a deposition tool 102 may be used to deposit the dielectric layer 312 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric layer 312 after the dielectric layer 312 is deposited.

As further shown in FIG. 12C, the series of semiconductor manufacturing operations 1200 includes forming the gate structure 224 over and/or on the dielectric layer 312 and the dielectric layer 314. As part of forming the gate structure 224, a deposition tool 102 may be used to deposit the conductive layer 310, the conductive layer 308, and/or the conductive core 306 in a CVD operation, a PVD operation, an ALD operation, an electroplating operation, another deposition operation described above in connection with FIG. 1, and/or another suitable deposition operation. In some implementations, a seed layer is deposited prior to deposition of conductive layer 310, the conductive layer 308, and/or the conductive core 306. In some implementations, a planarization tool 110 may be used to planarize the conductive layer 310, the conductive layer 308, and/or the conductive core 306 after the conductive layer 310, the conductive layer 308, and/or the conductive core 306 is deposited.

As indicated above, FIGS. 12A-12C are provided as an example. Other examples may differ from what is describe with regards to FIGS. 12A-12C.

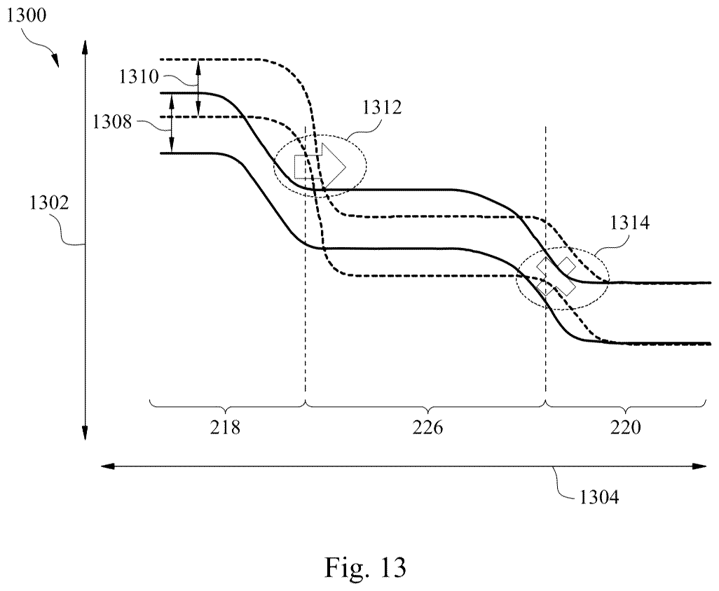

FIG. 13 is a diagram of example performance data 1300 of a transistor structure described herein. In some implementations, the transistor structure corresponds to the TFET structure 222 having a P-N-I-N-N structure as described in connection with FIGS. 4A and 4B. The example performance data 1300 includes a band gap energy level(s) 1302 in relation to a position 1304 across a fin structure (e.g., the fin structure 206).

The data includes a difference in band gap energy levels for regions and/or junctions across the fin structure, and contrasts a difference 1308 for a transistor structure including a uniform channel (e.g., a channel of intrinsic silicon) versus a difference 1310 for a transistor structure including a non-uniform channel (e.g., the TFET structure 222 including the doped semiconductor region 402, the doped semiconductor region 406, an intrinsic region of the fin structure 206, the doped semiconductor region 408, and the doped semiconductor region 404).

FIG. 13 shows a region 1312 (e.g., a source-to-channel region near the source side). As shown in the region 1312, a steepness of a gap between energy levels associated with the difference 1308 is greater than a steepness of a gap between energy levels associated with the difference 1310. Furthermore, and within the region 1312, a width of the gap associated with the difference 1308 is less than the width of the gap associated with the difference 1310. Such a difference in steepness and/or widths may contribute an increased charge carrier flow (e.g., current flow) for the P-N-I-N-N structure within the region 1312.

FIG. 13 further shows a region 1314 (e.g., a channel-to-drain region near the drain side) in which the difference 1310 is increased relative to the difference 1308. As shown in the region 1314, a steepness of a gap between energy levels associated with the difference 1308 is less than a steepness of a gap between energy levels associated with the difference 1310. Such a difference in steepness may contribute to a decreased charge carrier flow (e.g., current flow) for the P-N-I-N-N structure within the region 1314.

As indicated above, FIG. 13 is provided as an example. Other examples may differ from what is describe with regards to FIG. 13.

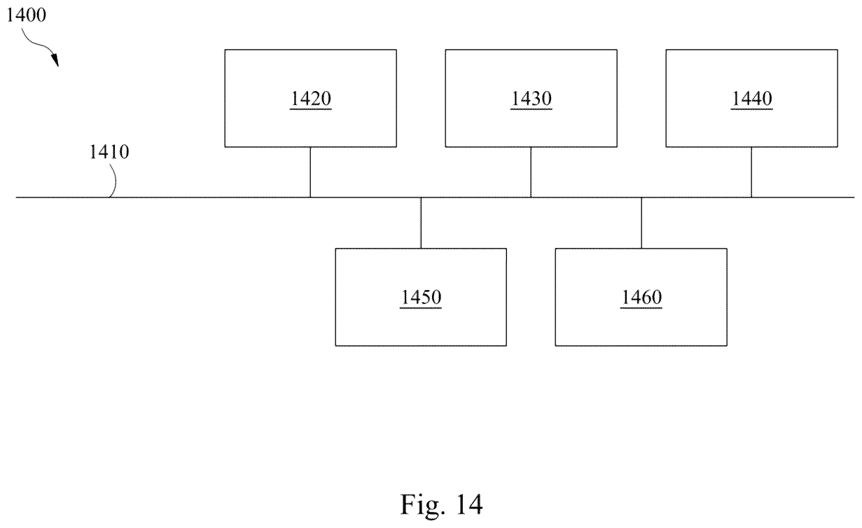

FIG. 14 is a diagram of example components of one or more devices of FIG. 1 described herein. The device 1400 may correspond to one or more of the semiconductor processing tools 102-114 and/or the wafer/die transport tool 116 described in connection with FIG. 1. In some implementations, one or more of the semiconductor processing tools 102-114 and/or the wafer/die transport tool 116 may include one or more devices 1400 and/or one or more components of the device 1400. As shown in FIG. 14, the device 1400 may include a bus 1410, a processor 1420, a memory 1430, an input component 1440, an output component 1450, and/or a communication component 1460.

The bus 1410 may include one or more components that enable wired and/or wireless communication among the components of the device 1400. The bus 1410 may couple together two or more components of FIG. 14, such as via operative coupling, communicative coupling, electronic coupling, and/or electric coupling. For example, the bus 1410 may include an electrical connection (e.g., a wire, a trace, and/or a lead) and/or a wireless bus. The processor 1420 may include a central processing unit, a graphics processing unit, a microprocessor, a controller, a microcontroller, a digital signal processor, a field-programmable gate array, an application-specific integrated circuit, and/or another type of processing component. The processor 1420 may be implemented in hardware, firmware, or a combination of hardware and software. In some implementations, the processor 1420 may include one or more processors capable of being programmed to perform one or more operations or processes described elsewhere herein.

The memory 1430 may include volatile and/or nonvolatile memory. For example, the memory 1430 may include random access memory (RAM), read only memory (ROM), a hard disk drive, and/or another type of memory (e.g., a flash memory, a magnetic memory, and/or an optical memory). The memory 1430 may include internal memory (e.g., RAM, ROM, or a hard disk drive) and/or removable memory (e.g., removable via a universal serial bus connection). The memory 1430 may be a non-transitory computer-readable medium. The memory 1430 may store information, one or more instructions, and/or software (e.g., one or more software applications) related to the operation of the device 1400. In some implementations, the memory 1430 may include one or more memories that are coupled (e.g., communicatively coupled) to one or more processors (e.g., processor 1420), such as via the bus 1410. Communicative coupling between a processor 1420 and a memory 1430 may enable the processor 1420 to read and/or process information stored in the memory 1430 and/or to store information in the memory 1430.

The input component 1440 may enable the device 1400 to receive input, such as user input and/or sensed input. For example, the input component 1440 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1450 may enable the device 1400 to provide output, such as via a display, a speaker, and/or a light-emitting diode. The communication component 1460 may enable the device 1400 to communicate with other devices via a wired connection and/or a wireless connection. For example, the communication component 1460 may include a receiver, a transmitter, a transceiver, a modem, a network interface card, and/or an antenna.

The device 1400 may perform one or more operations or processes described herein. For example, a non-transitory computer-readable medium (e.g., memory 1430) may store a set of instructions (e.g., one or more instructions or code) for execution by the processor 1420. The processor 1420 may execute the set of instructions to perform one or more operations or processes described herein. In some implementations, execution of the set of instructions, by one or more processors 1420, causes the one or more processors 1420 and/or the device 1400 to perform one or more operations or processes described herein. In some implementations, hardwired circuitry may be used instead of or in combination with the instructions to perform one or more operations or processes described herein. Additionally, or alternatively, the processor 1420 may be configured to perform one or more operations or processes described herein. Thus, implementations described herein are not limited to any specific combination of hardware circuitry and software.

The number and arrangement of components shown in FIG. 14 are provided as an example. The device 1400 may include additional components, fewer components, different components, or differently arranged components than those shown in FIG. 14. Additionally, or alternatively, a set of components (e.g., one or more components) of the device 1400 may perform one or more functions described as being performed by another set of components of the device 1400.

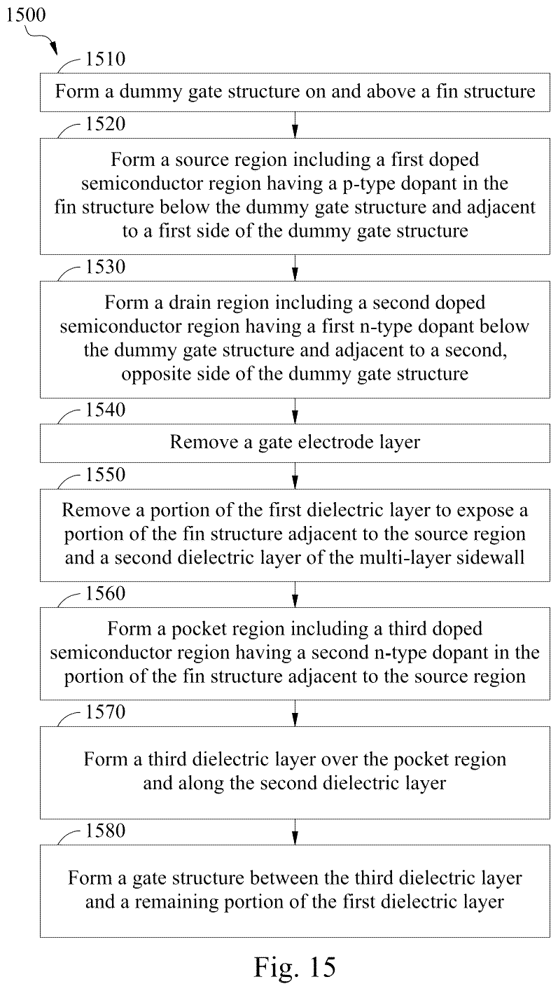

FIG. 15 is a flowchart of an example process 1500 associated with forming a semiconductor device described herein (e.g., the semiconductor device 200 including the TFET structure 222). In some implementations, one or more process blocks of FIG. 15 are performed using one or more semiconductor processing tools (e.g., one or more of the semiconductor processing tools 102-114). Additionally, or alternatively, one or more process blocks of FIG. 15 may be performed using one or more components of device 1400, such as processor 1420, memory 1430, input component 1440, output component 1450, and/or communication component 1460.

As shown in FIG. 15, process 1500 may include forming a dummy gate structure on and above a fin structure (block 1510). For example, one or more of the semiconductor processing tools 102-114 may be used to form a dummy gate structure (e.g., the dummy gate structure 210) on and above a fin structure (e.g., the fin structure 206), as described herein. In some implementations, the dummy gate structure includes a gate electrode layer (e.g., the gate electrode layer 212) that is surrounded by a multi-layer sidewall including a first dielectric layer (e.g., the dielectric layer 314) that is on the gate electrode layer.

As further shown in FIG. 15, process 1500 may include forming a source region including a first doped semiconductor region having a p-type dopant in the fin structure below the dummy gate structure and adjacent to a first side of the dummy gate structure (block 1520). For example, one or more of the semiconductor processing tools 102-114 may be used to form a source region (e.g., the source region 218) including a first doped semiconductor region having a p-type dopant (e.g., the doped semiconductor region 402) in the fin structure below the dummy gate structure and adjacent to a first side of the dummy gate structure, as described herein.

As further shown in FIG. 15, process 1500 may include forming a drain region including a second semiconductor region having a first n-type dopant below the dummy gate structure and adjacent to a second, opposite side of the dummy gate structure (block 1530). For example, one or more of the semiconductor processing tools 102-114 may be used to form a drain region (e.g., the drain region 220) including a second doped semiconductor region having a first n-type dopant (e.g., the doped semiconductor region 406) below the dummy gate structure and adjacent to a second, opposite side of the dummy gate structure, as described herein.

As further shown in FIG. 15, process 1500 may include removing the gate electrode layer (block 1540). For example, one or more of the semiconductor processing tools 102-114 may be used to remove the gate electrode layer, as described herein.

As further shown in FIG. 15, process 1500 may include removing a portion of the first dielectric layer to expose a portion of the fin structure adjacent to the source region and a second dielectric layer of the multi-layer sidewall (block 1550). For example, one or more of the semiconductor processing tools 102-114 may be used to remove a portion of the first dielectric layer to expose a portion of the fin structure adjacent to the source region and a second dielectric layer (e.g., the sidewall spacer layer 314) of the multi-layer sidewall, as described herein.

As further shown in FIG. 15, process 1500 may include forming a pocket region including a third doped semiconductor region having a second n-type dopant in the portion of the fin structure adjacent to the source region (block 1560). For example, one or more of the semiconductor processing tools 102-114 may be used to form a pocket region including a third doped semiconductor region having a second n-type dopant in (e.g., the doped semiconductor region 410) in the portion of the fin structure adjacent to the source region, as described herein.

As further shown in FIG. 15, process 1500 may include forming a third dielectric layer over the pocket region and along the second dielectric layer (block 1570). For example, one or more of the semiconductor processing tools 102-114 may be used to form a third dielectric layer (e.g., the dielectric layer 312) over the pocket region and along the second dielectric layer, as described herein.

As further shown in FIG. 15, process 1500 may include forming a gate structure between the third dielectric layer and a remaining portion of the first dielectric layer (block 1580). For example, one or more of the semiconductor processing tools 102-114 may be used to form a gate structure (e.g., the gate structure 224) between the third dielectric layer and a remaining portion of the first dielectric layer, as described herein. In some implementations, forming the gate structure includes forming one or more layers of a conductive material (e.g., the conductive layer 308 and/or the conductive layer 310) between the third dielectric layer and the remaining portion of the first dielectric layer.

Process 1500 may include additional implementations, such as any single implementation or any combination of implementations described below and/or in connection with one or more other processes described elsewhere herein.

In a first implementation, process 1500 includes forming a first portion (e.g., the portion 802) of the fin structure to include a first thickness (e.g., the thickness D7) and forming a second portion (e.g., the portion 804) of the fin structure to include a second thickness (e.g., the thickness D8), where the second thickness is greater than the first thickness.

In a second implementation, alone or in combination with the first implementation, process 1500 includes forming a capping layer (e.g., the doped semiconductor region 902) on a surface of the first portion using an epitaxial growth operation.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

Some implementations described herein include a semiconductor device including a TFET structure and methods of manufacturing. The TFET structure includes different combinations of doped semiconductor regions that form a source region, a drain region, and a channel region of the TFET. The different combinations of doped semiconductor regions include different types of dopants, different concentrations of dopants, and/or dopant gradients that change differences in band gap energy levels across one or more junctions of the TFET structure.

In this way, a performance of the TFET structure is increased such that the TFET structure is compatible with an available power supply. Furthermore, leakage within the TFET structure may be reduced to increase a quality and/or a reliability of the TFET structure.

As described in greater detail above, some implementations described herein provide a structure. The structure includes a conductive core including a conductive material. The structure includes a first dielectric sidewall of a first dielectric material along a first side of the conductive core. The structure includes a second dielectric sidewall of a second dielectric material along a second, opposite side of the conductive core, where the second dielectric material is different than the first dielectric material. The structure includes a fin-shaped intrinsic semiconductor region having an interface region that connects with the first dielectric sidewall and the second dielectric sidewall and that is below the conductive core. The structure includes a first doped semiconductor region including a first dopant along a first side of the fin-shaped intrinsic semiconductor region that is proximate to the first dielectric sidewall. The structure includes a second doped semiconductor region including a second dopant along a second, opposite side of the fin-shaped intrinsic semiconductor region that is proximate to the second dielectric sidewall, where the second dopant is a different type of dopant than the first dopant.

As described in greater detail above, some implementations described herein provide a semiconductor device. The semiconductor device includes a tunneling fin-based transistor that includes a gate structure, a source region below the gate structure and proximate to a first side of the gate structure, a drain region below the gate structure and proximate to a second, opposite side of the gate structure, and a channel region between the source region and the drain region. The channel region includes a first portion having a first thickness near the source region and a second portion having a second thickness near the drain region, where the second thickness is greater than the first thickness.

As described in greater detail above, some implementations described herein provide a method. The method includes forming a dummy gate structure on and above a fin structure, where the dummy gate structure includes a gate electrode layer that is surrounded by a multi-layer sidewall including a first dielectric layer that is on the gate electrode layer. The method includes forming a source region including a first semiconductor region having a p-type dopant in the fin structure below the dummy gate structure and adjacent to a first side of the dummy gate structure. The method includes forming a drain region including a second semiconductor region having a first n-type dopant below the dummy gate structure and adjacent to a second, opposite side of the dummy gate structure. The method includes removing the gate electrode layer. The method includes removing a portion of the first dielectric layer to expose a portion of the fin structure adjacent to the source region and a second dielectric layer of the multi-layer sidewall. The method includes forming a pocket region including a second n-type dopant in the portion of the fin structure adjacent to the source region. The method includes forming a third dielectric layer over the pocket region and along the second dielectric layer. The method includes forming a gate structure between the third dielectric layer and a remaining portion of the first dielectric layer, where forming the gate structure includes forming one or more layers of a conductive material between the third dielectric layer and the remaining portion of the first dielectric layer.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like. The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a conductive core comprising a conductive material;
a first dielectric sidewall comprising a first dielectric material along a first side of the conductive core;
a second dielectric sidewall comprising a second dielectric material along a second, opposite side of the conductive core,
wherein the second dielectric material is different than the first dielectric material;
a fin-shaped intrinsic semiconductor region having an interface region that connects with the first dielectric sidewall and the second dielectric sidewall and that is below the conductive core;
a first doped semiconductor region comprising a first dopant along a first side of the fin-shaped intrinsic semiconductor region that is proximate to the first dielectric sidewall; and
a second doped semiconductor region comprising a second dopant along a second, opposite side of the fin-shaped intrinsic semiconductor region that is proximate to the second dielectric sidewall,
wherein the second dopant is a different dopant type than the first dopant.

2. The structure of claim 1, wherein the first dielectric material comprises a high-k dielectric material, and
wherein the second dielectric material comprises a low-k dielectric material.

3. The structure of claim 1, wherein the second dopant is a first electron-rich dopant and wherein the structure further comprises:
a third doped semiconductor region comprising a second electron-rich dopant,
wherein the third doped semiconductor region is along a perimeter of the first doped semiconductor region, and
wherein the third doped semiconductor region is between the first doped semiconductor region and the fin-shaped intrinsic semiconductor region.

4. The structure of claim 3, wherein a concentration of the second electron-rich dopant is less than a concentration of the first electron-rich dopant.

5. The structure of claim 3, further comprising:
a fourth doped semiconductor region comprising a third electron-rich dopant,
wherein the fourth doped semiconductor region is proximate the interface region and,
wherein the fourth doped semiconductor region is between the first doped semiconductor region and the fin-shaped intrinsic semiconductor region.

6. The structure of claim 5, wherein a concentration of the third electron-rich dopant is greater than a concentration of the second electron-rich dopant.

7. The structure of claim 5, further comprising:
a fifth doped semiconductor region comprising a fourth electron-rich dopant,
wherein the fifth doped semiconductor region is proximate the interface region, and
wherein the fifth doped semiconductor region is between the fourth doped semiconductor region and the second doped semiconductor region.

8. The structure of claim 7, wherein a concentration of the fourth electron-rich dopant is less than a concentration of the third electron-rich dopant.

9. The structure of claim 7, further comprising:
a sixth doped semiconductor region comprising a fifth electron-rich dopant,
wherein the sixth doped semiconductor region is between the second doped semiconductor region and the fin-shaped intrinsic semiconductor region, and
wherein a concentration of the fifth electron-rich dopant is less than a concentration of the first electron-rich dopant.

10. The structure of claim 9, wherein at least two of the first electron-rich dopant, the second electron-rich dopant, the third electron-rich dopant, the fourth electron-rich dopant, or the fifth electron-rich dopant are a same electron-rich dopant.

11. The structure of claim 9, wherein at least two of the first electron-rich dopant, the second electron-rich dopant, the third electron-rich dopant, the fourth electron-rich dopant, or the fifth electron-rich dopant are different electron-rich dopants.

12. A semiconductor device, comprising:
a tunneling fin-based transistor, comprising:
a gate structure;
a source region below the gate structure and proximate to a first side of the gate structure;
a drain region below the gate structure and proximate to a second, opposite side of the gate structure; and
a channel region between the source region and the drain region, comprising:
a first portion having a first thickness near the source region; and
a second portion having a second thickness near the drain region,
wherein the second thickness is different from the first thickness.

13. The semiconductor device of claim 12, wherein the source region comprises:
a p-type dopant, and
wherein the drain region comprises:
an n-type dopant.

14. The semiconductor device of claim 12, wherein the first portion comprises a first semiconductor material having a first band gap energy level, and
wherein the second portion comprises a second semiconductor material having a second band gap energy level,
wherein the second band gap energy level is greater than the first band gap energy level.

15. The semiconductor device of claim 12, wherein the first portion and the second portion comprise:
a same semiconductor material.

16. The semiconductor device of claim 12, further comprising:
a capping layer on the first portion,
wherein the capping layer is doped with an n-type dopant.

17. The semiconductor device of claim 12, wherein the first portion comprises a first semiconductor material and wherein the semiconductor device further comprises:
a capping layer on the first portion,
wherein the capping layer includes a second semiconductor material that is different than the first semiconductor material, and
wherein the second semiconductor material is doped with an n-type dopant.

18. A method, comprising:
forming a dummy gate structure on and above a fin structure,
wherein the dummy gate structure includes a gate electrode layer that is surrounded by a multi-layer sidewall including a first dielectric layer that is on the gate electrode layer;
forming a source region including a first doped semiconductor region having a p-type dopant in the fin structure below the dummy gate structure and adjacent to a first side of the dummy gate structure;
forming a drain region including a second doped semiconductor region having a first n-type dopant below the dummy gate structure and adjacent to a second, opposite side of the dummy gate structure;
removing the gate electrode layer;
removing a portion of the first dielectric layer to expose a portion of the fin structure adjacent to the source region and a second dielectric layer of the multi-layer sidewall;
forming a pocket region including a third doped semiconductor region having a second n-type dopant in the portion of the fin structure adjacent to the source region;
forming a third dielectric layer over the pocket region and along the second dielectric layer; and
forming a gate structure between the third dielectric layer and a remaining portion of the first dielectric layer,
wherein forming the gate structure includes forming one or more layers of a conductive material between the third dielectric layer and the remaining portion of the first dielectric layer.

19. The method of claim 18, further comprising:
forming a first portion of the fin structure to include a first thickness, and
forming a second portion of the fin structure to include a second thickness,
wherein the second thickness is greater than the first thickness.

20. The method of claim 19, further comprising:
forming a capping layer on a surface of the first portion using an epitaxial growth operation.
